(19) United States
(12) Patent Application Publication
(10) Pub. No.: US 2018/0254293 A1
(43) Pub. Date: Sep. 6, 2018

(54) ACTIVE MATRIX SUBSTRATE AND METHOD FOR PRODUCING SAME

(71) Applicant: SHARP KABUSHIKI KAISHA, Sakai City, Osaka (JP)

(72) Inventors: TOHRU OKABE, Sakai City (JP); HIROHIKO NISHIKI, Sakai City (JP); TAKESHI HARA, Sakai City (JP); TOMOHIRO KOSAKA, Sakai City (JP); IZUMI ISHIDA, Sakai City (JP); SHOGO MURASHIGE, Sakai City (JP)

(21) Appl. No.: 15/759,174

(22) PCT Filed: Sep. 7, 2016
(86) PCT No.: PCT/JP2016/076265

§ 371 Date: Mar. 9, 2018

(30) Foreign Application Priority Data
Sep. 10, 2015 (JP) 2015-178873

(51) Int. Cl. H01L 27/12; G02B 26/02

(52) U.S. Cl. CPC H01L 27/1262; H01L 27/1225; H01L 27/3244; H01L 27/1218; G02B 26/02; H01L 27/124

(57) ABSTRACT

An active matrix substrate 10 includes: an insulating substrate 110; a first conductive film 130 formed on the insulating substrate 110; a light-transmitting film 114 formed on the insulating substrate 110 so that the light-transmitting film 114 covers the first conductive film 130; a second conductive film 140 formed on the light-transmitting film 114; a first insulating layer 115 formed on the light-transmitting film 114 so that the first insulating layer 115 covers the second conductive film 140; a semiconductor film 170 formed on the first insulating layer 115; and a third conductive film 150 formed on the first insulating layer 115 and the semiconductor film 170. The first conductive film 130 and the second conductive film 140 are electrically connected via the third conductive film 150.

### TECHNICAL FIELD

The present invention relates to an active matrix substrate and a method for producing the same.

### BACKGROUND ART

Among display devices, some include active matrix substrates that include thin film transistors arranged in matrix (for example, Patent Document 1). In recent years, oxide semiconductors having characteristics such as high mobility and low leakage current are used as thin film transistors. The range of the use of an active matrix substrate that includes thin film transistors formed with an oxide semiconductor is extending. Such an active matrix substrate is used in, for example, a liquid crystal display that is required to be high-definition, a current-driven organic EL display in which heavy loads are applied on thin film transistors, a microelectromechanical system (MEMS) display that is required to control actions of shutters at a high speed, and the like.

For example, Patent Document 1 discloses an active matrix substrate that composes a display device. In the active matrix substrate of Patent Document 1, as illustrated in FIG. 30, signal lines 911 and gate lines 913a are in direct contact with each other, whereby the both are electrically connected.

### PRIOR ART DOCUMENT

### Patent Document

Patent Document 1: JP-A-2006-71946

### SUMMARY OF THE INVENTION

### Problem to be Solved by the Invention

The semiconductor layer of the active matrix substrate of Patent Document 1 is made of amorphous silicon. The temperature in the process for manufacturing the active matrix substrate of Patent Document 1 is at most about 300 to 330° C.

In contrast, in a case where the semiconductor film is made of oxide semiconductor, for example, an annealing treatment at 400° C. or higher is carried out for one to two hours with respect to an oxide semiconductor film in order to stabilize transistor properties of TFTs in which oxide semiconductor is used (hereinafter this annealing treatment at 400° C. or higher is also referred to as “a high-temperature annealing treatment”).

Incidentally, in a case where the active matrix substrate includes a light-transmitting film (SOG film), heat applied in the high-temperature annealing treatment tends to cause cracks and the like to occur in the SOG film, due to the properties of the SOG film. Particularly, in a case where protrusions and recesses such as contact holes and the like exist in the SOG film, cracks tend to occur when a high-temperature annealing treatment is carried out.

It is an object of the present invention to obtain an active matrix substrate and a display device characterized by the suppression of the occurrence of cracks and the like to the light-transmitting film, which improves the yield and the reliability of the products, and to obtain a method for producing such an active matrix substrate.

### Means to Solve the Problem

The display device of the present invention includes: an insulating substrate; a first conductive film formed on the insulating substrate; a light-transmitting film formed on the insulating substrate so that the light-transmitting film covers the first conductive film; a second conductive film formed on the light-transmitting film; a first insulating layer formed on the light-transmitting film so that the first insulating layer covers the second conductive film; a semiconductor film formed on the first insulating layer; and a third conductive film formed on the first insulating layer and the semiconductor film. The first conductive film and the second conductive film are electrically connected via the third conductive film.

A method for producing an active matrix substrate according to the present invention includes: a first step of forming a first conductive film on an insulating substrate; a second step of forming a light-transmitting film on the insulating substrate so that the light-transmitting film covers the first conductive film; a third step of forming a second conductive film on the light-transmitting film; a fourth step of forming a first insulating layer on the light-transmitting film so that the first insulating layer covers the second conductive film; a fifth step of forming a semiconductor film on the first insulating layer, and thereafter, subjecting the semiconductor film to an annealing treatment; a sixth step of forming a first contact hole that passes through the first insulating layer and the light-transmitting film and reaches the first conductive film, and a second contact hole that passes through the first insulating layer and reaches the second conductive film; and a seventh step of forming a third conductive film on the first insulating layer and the semiconductor film. The fifth step is executed prior to the formation of the first contact hole in the light-transmitting film in the sixth step, and in the seventh step, the first conductive film and the third conductive film are in contact with each other in the first contact hole, which passes through the light-transmitting film and the first insulating layer, and the second conductive film and the third conductive film are in contact with each other in the second contact hole, which passes through the first insulating layer, whereby the first conductive film and the second conductive film are electrically connected.

### Effect of the Invention

With the present invention, it is possible to obtain an active matrix substrate and a display device characterized by the suppression of the occurrence of cracks and the like to the light-transmitting film, which improves the yield and the reliability of the products, and to obtain a method for producing such an active matrix substrate.

### BRIEF DESCRIPTION OF DRAWINGS

FIG. 1 is a perspective view illustrating a schematic configuration of a display device of Embodiment 1.

FIG. 2 is an equivalent circuit diagram of he display device of Embodiment 1.

FIG. 3 is a perspective view of a shutter portion.

FIG. 4 is a plan view illustrating an operation of the shutter portion.

FIG. 5 is a cross-sectional view taken along line V-V in FIG. 4.

FIG. 6 is a plan view illustrating an operation of the shutter portion.

FIG. 7 is a cross-sectional view taken along line VII-VII in FIG. 6.

FIG. 8 is a plan view illustrating a part (corresponding to one pixel) of a first substrate.

FIG. 9 is a cross-sectional view taken along line A-A in FIG. 8.

FIG. 10 is a cross-sectional view taken along line B-B in FIG. 8.

FIG. 11 is an explanatory view illustrating a method for producing a first substrate.

FIG. 12 is an explanatory view illustrating the method for producing the first substrate.

FIG. 13 is an explanatory view illustrating the method for producing the first substrate.

FIG. 14 is an explanatory view illustrating the method for producing the first substrate.

FIG. 15 is an explanatory view illustrating the method for producing the first substrate.

FIG. 16 is an explanatory view illustrating the method for producing the first substrate.

FIG. 17 is an explanatory view illustrating the method for producing the first substrate.

FIG. 18 is an explanatory view illustrating the method for producing the first substrate.

FIG. 19 is an explanatory view illustrating the method for producing the first substrate.

FIG. 20 is an explanatory view illustrating the method for producing the first substrate.

FIG. 21 is an explanatory view illustrating the method for producing the first substrate.

FIG. 22 is a cross-sectional view of a first substrate of a modification example of Embodiment 1.

FIG. 23 is an explanatory view illustrating a method for producing the first substrate of the modification example of Embodiment 1.

FIG. 24 is an explanatory view illustrating the method for producing the first substrate of the modification example of Embodiment 1.

FIG. 25 is an explanatory view illustrating the method for producing the first substrate of the modification example of Embodiment 1.

FIG. 26 is a perspective view illustrating a schematic configuration of a display device of Embodiment 2.

FIG. 27 is an equivalent circuit diagram of the display device of Embodiment 2.

FIG. 28 is a perspective view illustrating a schematic configuration of a display device of a modification example of Embodiment 2.

FIG. 29 is a perspective view illustrating a schematic configuration of a display device of Embodiment 3.

FIG. 30 is an explanatory view illustrating a process of producing an active matrix substrate of a conventional configuration.

### MODE FOR CARRYING OUT THE Invention

The display device of the present invention includes: an insulating substrate; a first conductive film formed on the insulating substrate; a light-transmitting film formed on the insulating substrate so that the light-transmitting film covers the first conductive film; a second conductive film formed on the light-transmitting film; a first insulating layer formed on the light-transmitting film so that the first insulating layer covers the second conductive film; a semiconductor film formed on the first insulating layer; and a third conductive film formed on the first insulating layer and the semiconductor film. The first conductive film and the second conductive film are electrically connected via the third conductive film.

According to the above-described configuration, the connection between the first conductive film and the second conductive film is achieved through the third conductive film. More specifically, the first conductive film and the third conductive film are electrically connected with each other, and the second conductive film and the third conductive film are electrically connected with each other. This causes the first conductive film and the second conductive film to be electrically connected, which makes it unnecessary to provide a contact hole in the light-transmitting film so as to bring the first conductive film and the second conductive film into direct contact with each other. This therefore makes it unnecessary to form a contact hole in the light-transmitting film before forming the second conductive film.

Since it is unnecessary to form a contact hole in the light-transmitting film before forming the second conductive film, it is possible to form the first insulating film and the semiconductor film in a state in which no contact hole is formed in the light-transmitting film. In other words, in a state in which no contact hole is formed in the light-transmitting film, the semiconductor film can be subjected to a high-temperature treatment (for example, a high-temperature annealing treatment). When the semiconductor film is subjected to a high-temperature treatment such as annealing or the like, therefore, the light-transmitting film has no contact hole therein and hence it is flat. This makes it possible to prevent cracks from occurring to the light-transmitting film due to heat applied thereto. As a result, the yield and reliability of the active matrix substrate can be improved.

Preferably, the first conductive film and the third conductive film of the active matrix substrate of the present invention are in contact with each other in a first contact hole that passes through the light-transmitting film and the first insulating layer, and the second conductive film and the third conductive film are in contact with each other in a second contact hole that passes through the first insulating layer, whereby the first conductive film and the second conductive film are electrically connected with each other.

According to the above-described configuration, the first contact hole allowing the first conductive film and the third conductive film to be electrically connected with each other passes through the light-transmitting film and the first insulating layer. This makes it possible to form the first contact hole after subjecting the semiconductor film to high-temperature annealing treatment. Besides, the second contact hole allowing the second conductive film and the third conductive film to be electrically connected with each other passes through the first insulating film. This therefore makes it possible to form the second contact hole after subjecting the semiconductor film to a high-temperature annealing treatment. With the above-described configuration, therefore, it is possible to electrically connect the first conductive film and the second conductive film via the third conductive film after subjecting the semiconductor film to a high-temperature annealing treatment.

The active matrix substrate of the present invention preferably further includes: a second insulating layer formed on the first insulating layer so that the second insulating layer covers the third conductive film; and a fourth conductive film formed on the second insulating layer.

The active matrix substrate of the present invention preferably further includes a light-shielding film formed on the insulating substrate, and the first conductive film is provided on the insulating substrate and the light-shielding film.

According to the above-described configuration, the active matrix substrate includes a light-shielding film on the insulating substrate. This makes it possible to prevent light incident from the insulating substrate side onto the active matrix substrate from being reflected on the first conductive film, thereby obtaining excellent visibility.

The light-transmitting film of the active matrix substrate of the present invention is preferably an SOG film.

The first conductive film of the active matrix substrate of the present invention preferably has a film thickness of 500 to 1000 nm.

The semiconductor film of the active matrix substrate of the present invention is preferably formed with an oxide semiconductor.

A display device of the present invention includes the above-described active matrix substrate.

The display device of the present invention may be a MEMS display that further includes: a light-shielding film that is provided between the insulating substrate and the insulating light-transmitting film, and that has a plurality of openings; shutter mechanism parts formed in an upper layer with respect to the third conductive film; and a backlight arranged so as to be opposed to the insulating substrate, with the shutter mechanism parts being interposed therebetween, wherein the shutter mechanism parts include shutter bodies that control amount of light of the backlight that passes through the openings provided in the light-shielding film.

The display device of the present invention may be a liquid crystal display device that includes: a counter substrate opposed to the active matrix substrate; and a liquid crystal layer provided between the active matrix substrate and the counter substrate.

The display device of the present invention may be an organic EL device that further includes an organic EL element formed in an upper layer with respect to the third conductive film.

A method for producing an active matrix substrate according to the present invention includes: a first step of forming a first conductive film on an insulating substrate; a second step of forming a light-transmitting film on the insulating substrate so as to cover the first conductive film; a third step of forming a second conductive film on the light-transmitting film; a fourth step of forming a first insulating layer on the light-transmitting film so as to cover the second conductive film; a fifth step of forming a semiconductor film on the first insulating layer, and thereafter, performing an annealing treatment; a sixth step of forming a first contact hole that passes through the first insulating layer and the light-transmitting film and reaches the first conductive film, and a second contact hole that passes through the first insulating layer and reaches the second conductive film; and a seventh step of forming a third conductive film on the first insulating layer and the semiconductor film. The fifth step is executed prior to the formation of the first contact hole in the light-transmitting film in the sixth step, and in the seventh step, the first conductive film and the third conductive film are electrically connected with each other via the first contact hole, and the second conductive film and the third conductive film are electrically connected with each other via the second contact hole.

According to the above-described method for producing an active matrix substrate, the semiconductor film is annealed in the fifth step, and thereafter, the first contact hole is formed in the light-transmitting film in the sixth step. This results in that in the fifth step, the annealing treatment is performed in a state in which no contact hole is formed in the light-transmitting film, that is, in a state in which the light-transmitting film is flat. This therefore makes it possible to prevent cracks from occurring in the light-transmitting film due to heat of the annealing treatment. Cracks are prevented from occurring in the light-transmitting film, and consequently, the yield of the active matrix substrate can be improved.

In the method for producing an active matrix substrate according to the present invention, in the sixth step, the first insulating layer may be patterned so that a part of the first contact hole as well as the second contact hole are formed, and thereafter the light-transmitting film may be patterned so that the first contact hole is formed.

The semiconductor film in the method for producing an active matrix substrate according to the present invention is preferably formed with an oxide semiconductor.

The following describes preferred embodiments of the present invention in detail, while referring to the drawings. The drawings referred to in the following description illustrate, for convenience of description, only the principal members necessary for describing the present invention, among the constituent members in the embodiments, in a simplified manner. The present invention, therefore, may include arbitrary constituent members that are not described in the descriptions of the following embodiments. Further, the dimension ratios of the constituent members illustrated in the drawings do not necessarily indicate the real sizes, the real dimension ratios, etc.

### Embodiment 1

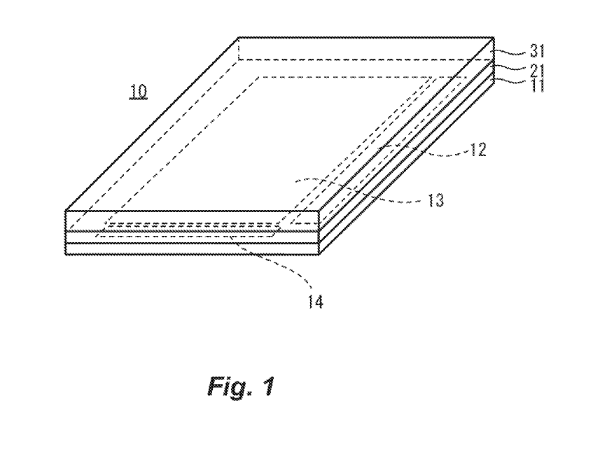

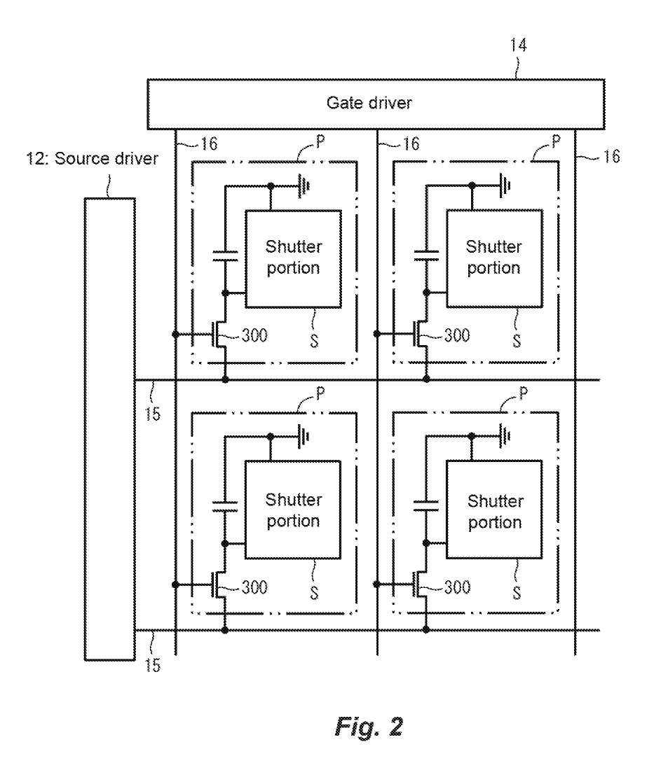

FIG. 1 is a perspective view illustrating an exemplary configuration of a display device in Embodiment 1. FIG. 2 is an equivalent circuit diagram of the display device 10. The display device 10 illustrated in FIG. 1 is a transmission type MEMS display. The display device 10 has a configuration in which a first substrate 11, a second substrate 21, and a backlight 31 are laminated in the stated order.

The first substrate 11 includes a display area 13 in which pixels P for displaying images are arranged, as well as a source driver 12 and a gate driver 14 that supply signals for controlling the transmission of light of each pixel P. The second substrate 21 is provided so as to cover a backlight surface of the backlight 31.

The backlight 31 includes, for example, a red color (R) light source, a green color (G) light source, and a blue color (B) light source so as to project back light to each pixel P. The backlight 31, based on backlight control signals input thereto, causes a prescribed light source to emit light.

As illustrated in FIG. 2, a plurality of source lines 15, a plurality of gate lines 16 extending so as to intersect with the source lines 15 are provided on the first substrate 11, and pixels P are formed with the source lines 15 and the gate lines 16.

Each source line 15 is connected to the source driver 12, and each gate line 16 is connected to the gate driver 14. The gate driver 14 sequentially inputs, to each gate line 16, a gate signal that switches the gate line 16 to a selected state or a non-selected state, thereby scanning the gate lines 16. The source driver 12 inputs data signals to each source line 15 in synchronization with the scanning of the gate lines 16. This causes desired signal voltages to be applied to respective shutter portions S of the pixels P connected to the selected gate line 16.

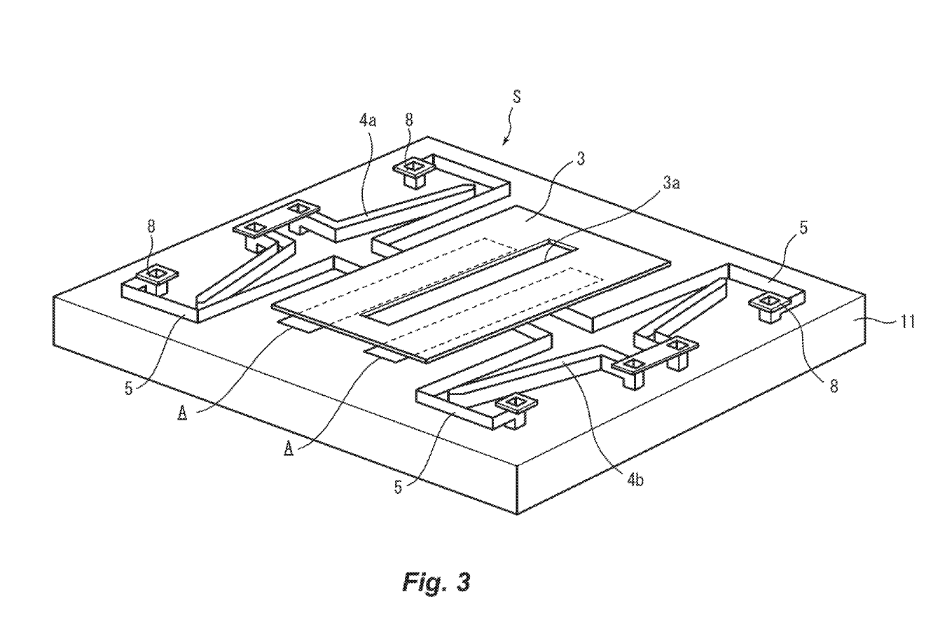

FIG. 3 is a perspective view illustrating a detailed exemplary configuration of the shutter portion S at one pixel P. The shutter portions S includes a shutter body 3, a first electrode portion 4a, a second electrode portion 4b, and a shutter beam 5.

The shutter body 3 has a plate-like shape. In FIG. 3, for convenience sake of illustration, the shutter body 3 is illustrated as having a flat plate shape, but actually, as illustrated in the cross-sectional views in FIG. 5 or 7 to be described below, the shutter body 3 has a shape having folds in the lengthwise direction of the shutter body 3. The direction vertical to the lengthwise direction (long side direction) of the shutter body 3, that is, the transverse direction (short side direction), is a direction in which the shutter body 3 is driven (movement direction). The shutter body 3 has an opening 3a that extends in the lengthwise direction. The opening 3a is formed in a rectangular shape having long sides extending in the lengthwise direction of the shutter body 3.

A predetermined voltage is applied to the first electrode portion 4a and the second electrode portion 4b, as is described below. Each of the first electrode portion 4a and the second electrode portion 4b includes two driving beams 6, and a driving beam anchor 7. The two driving beams 6 are arranged so as to be opposed to the shutter beam 5. The driving beam anchor 7 is electrically connected to the two driving beams 6. Further, the driving beam anchor 7 supports the two driving beams 6.

The shutter body 3 is connected to one end of each shutter beam 5. The other end of each shutter beam 5 is connected to the shutter beam anchor 8 fixed to the first substrate 11. The shutter beams 5 are connected to end portions in the driving direction of the shutter body 3, respectively. The shutter beams 5 extend from the portions connected with the shutter body 3 outward, and further extend along the end portions in the driving direction of the shutter body 3, to be connected to the shutter beam anchors 8. The shutter beams 5 have flexibility. The shutter body 3 is supported in a state movable with respect to the first substrate 11, by the shutter beam anchors 8 fixed to the first substrate 11, and the shutter beams 5 that have flexibility and that connect the shutter beam anchors 8 and the shutter body 3. Further, the shutter body 3 is electrically connected through the shutter beam anchors 8 and the shutter beams 5 to the lines provided on the first substrate 11.

The first substrate 11 has light-transmitting areas A as illustrated in FIG. 3. The light-transmitting area A has, for example, a rectangular shape corresponding to the opening 3a of the shutter body 3. For example, two light-transmitting areas A are provided with respect to one shutter body 3. The two light-transmitting areas A are arranged so as to be arrayed in the short side direction of the shutter body 3. In a case where no electric force is exerted between the shutter body 3 and the first electrode portion 4a, and between the shutter body 3 and the second electrode portion 4b, the most part of the opening 3a of the shutter body 3 is in a state of not overlapping with the light-transmitting areas A.

In the present embodiment, the driving circuit that controls the shutter portion S supplies potentials having different polarities to the first electrode portion 4a and the second electrode portion 4b, respectively, the polarities varying at intervals of fixed time. Further, the driving circuit that controls the shutter portion S supplies a fixed potential having a positive polarity or a negative polarity to the shutter body 3.

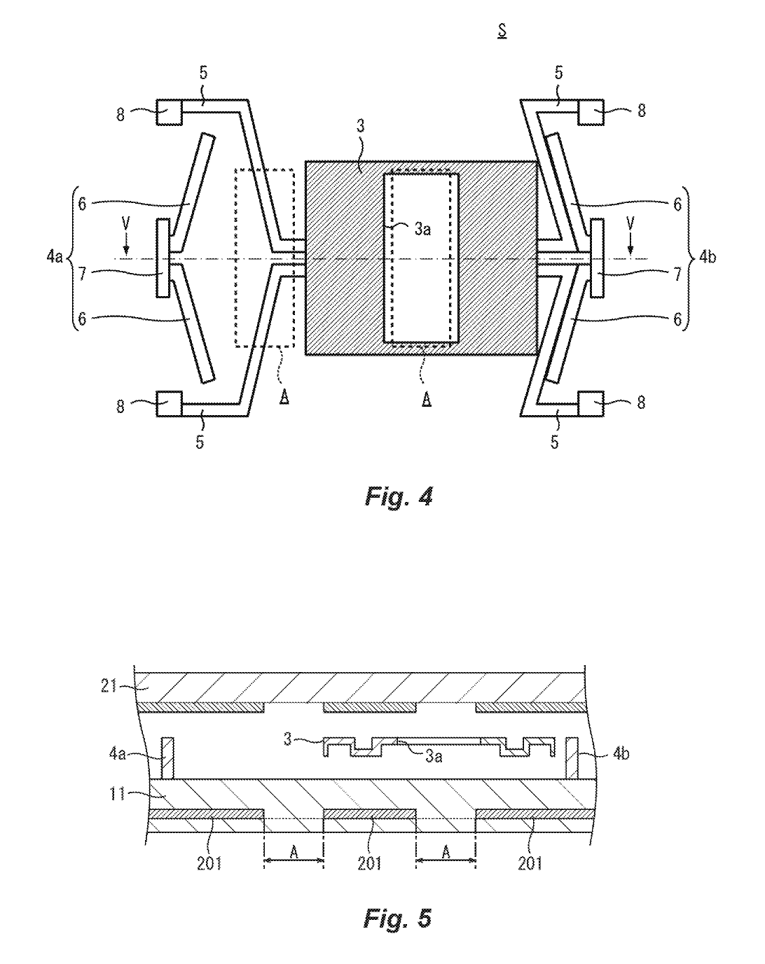

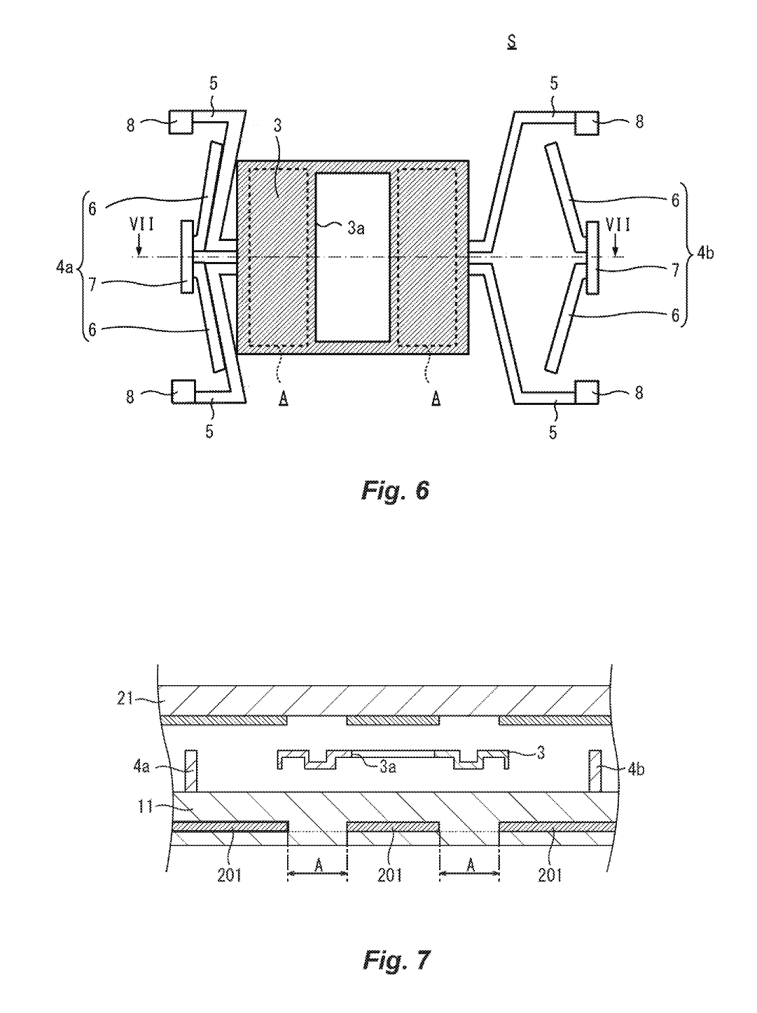

The following description describes an exemplary case where a potential at a high (H) level is supplied to the shutter body 3. When the driving beam 6 of the first electrode portion 4a has a potential at H level and the driving beam 6 of the second electrode portion 4b has a potential at low (L) level, electrostatic force causes the shutter body 3 to move toward the side of the second electrode portion 4b having a potential at L level. As a result, as illustrated in FIGS. 4 and 5, the opening 3a of the shutter body 3 overlaps the light-transmitting area A, whereby the state shifts to an opened state in which light from the backlight 31 passes therethrough to the first substrate 11 side. When the potential of the first electrode portion 4a is at L level and the potential of the second electrode portion 4b is at H level, the shutter body 3 moves toward the first electrode portion 4a side. Then, as illustrated in FIGS. 6 and 7, the portion other than the opening 3a of the shutter body 3 overlaps the light-transmitting area A of the first substrate 11. In this case, the state shifts to a closed state in which light from the backlight 31 does not pass toward the first substrate 11 side. In the shutter portions S of the present embodiment, therefore, the shutter body 3 is moved by controlling the potentials of the shutter body 3, the first electrode portion 4a, and the second electrode portion 4b, so as to switch the opened state and the closed state of the light-transmitting area A. In a case where a potential at L level is supplied to the shutter body 3, the shutter body 3 makes an operation reverse to that described above.

### First Substrate

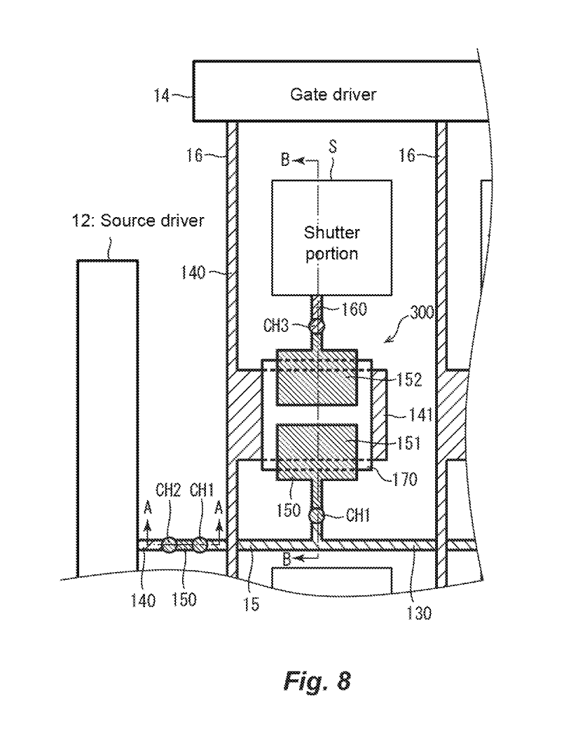

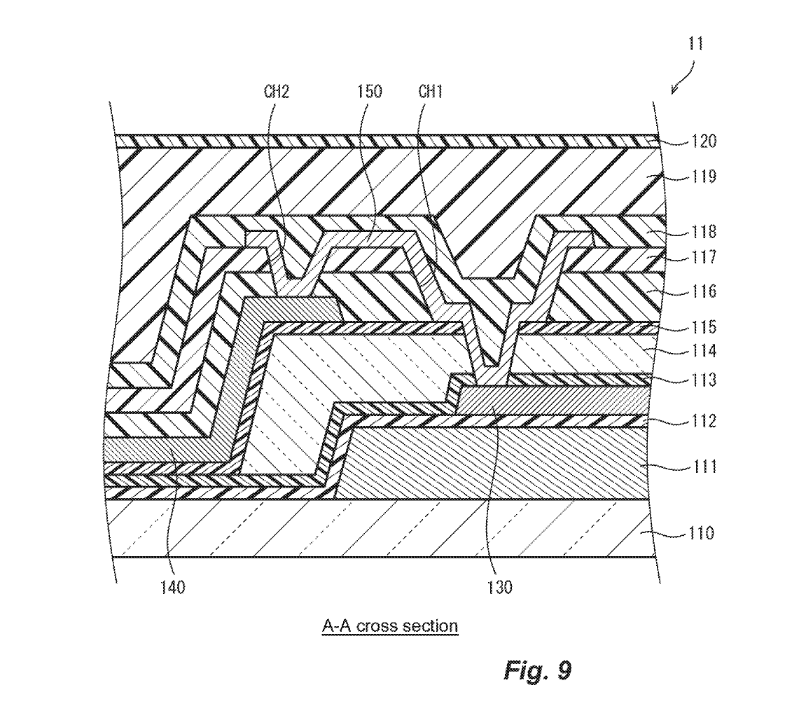

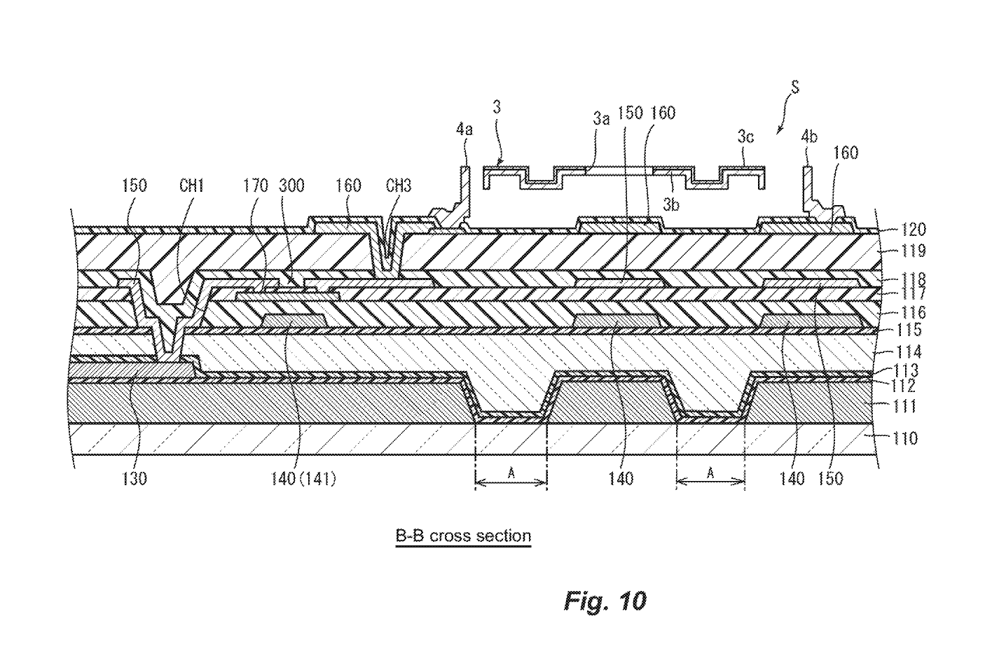

FIG. 8 is a plan view illustrating one pixel, a part of the source driver 12, and a part of the gate driver 14, of the first substrate 11. FIG. 9 is a cross-sectional view taken along line A-A in FIG. 8. FIG. 10 is a cross-sectional view taken along line B-B in FIG. 8.

The first substrate 11 has a configuration in which a light-shielding film 111, a first inorganic insulating film 112, a second inorganic insulating film 113, a light-transmitting film 114. a third inorganic insulating film 115, a gate insulating film 116, an etching stopper film 117, a passivation film 118, an organic insulating film 119, and a fourth inorganic insulating film 120 are laminated in the stated order on the insulating substrate 110, as illustrated in FIGS. 9 and 10. Between the first inorganic insulating film 112 and the second inorganic insulating film 113, there is provided a first conductive film 130, as illustrated in FIGS. 9 and 10. Between the third inorganic insulating film 115 and the gate insulating film 116, there is provided a second conductive film 140, as illustrated in FIGS. 9 and 10. Between the etching stopper film 117 and the passivation film 118. there is provided a third conductive film 150, as illustrated in FIGS. 9 and 10. Between the organic insulating film 119 and the fourth inorganic insulating film 120, there is provided a fourth conductive film 160, as illustrated in FIG. 10.

As illustrated in FIG. 10, a semiconductor film 170 is provided between the gate insulating film 116 and the etching stopper film 117. The semiconductor film 170 composes the TFT 300. The TFT 300 includes a gate electrode 141 formed with the second conductive film 140, the semiconductor film 170, the etching stopper film 117, as well as the source electrode 151 and the drain electrode 152 formed with the third conductive film 150. The TFT 300 has a conventionally known configuration. Though one TFT is illustrated in FIG. 8, a single pixel P actually includes a plurality of TFTs.

Further, as illustrated in FIG. 10, the shutter portion S is formed on the fourth inorganic insulating film 120. The configuration of the shutter portion S is as mentioned above. The shutter body 3 has a configuration of a laminate obtained by laminating the shutter main body 3b and the metal film 3c on the insulating substrate 110 side.

The light-shielding film 111 is provided on the insulating substrate 110. As illustrated in FIG. 9, the light-shielding film 111 is formed so as to cover the display area 13 other than the light-transmitting area A. This makes it possible to prevent external light coming from the display viewing side and entering the display device 10 from going over the light-shielding film 111 to the second substrate 21 side.

The light-shielding film 111 is formed with a material that hardly reflects light. This makes it possible to prevent external light that has advanced from the display viewing side into the display device 10 from being reflected by the light-shielding film 111 and going back to the display viewing side. Further, the light-shielding film 111 is formed with the material having a high resistance. This makes it possible to prevent a great parasitic capacitance from being generated between the light-shielding film 111 and conductive films forming the TFTs 300 and the like. Still further, since the light-shielding film 111 is formed prior to the TFT manufacturing process, it is necessary to select, as a material for light-shielding film 111, a material that has less influence to TFT properties in subsequent processing operations in the TFT manufacturing process, and that withstand the processing operations in the TFT manufacturing process. Examples of the material of the light-shielding film 111 that satisfy such requirements include, for example, a high-melting-point resin film (polyimide, etc.) and a spin-on-glass (SOG) film that are colored in a dark color. Still further, the light-shielding film 111, for example, can contain carbon black so as to be colored in a dark color.

The first inorganic insulating film 112 is provided so as to cover the insulating substrate 110 and the light-shielding film 111.

The first conductive film 130 is provided on the first inorganic insulating film 112. As illustrated in FIG. 8, the first conductive film 130 forms a part of the source line 15 and the like.

The second inorganic insulating film 113 is provided so as to cover the first inorganic insulating film 112 and the first conductive film 130.

The light-transmitting film 114 is provided so as to cover the second inorganic insulating film 113. The light-transmitting film 114 fills in areas where the light-shielding film 111 is not provided when viewed in the vertical direction with respect to the insulating substrate 110, whereby the steps formed due to the light-shielding film 111 are canceled. Further, the light-transmitting film 114 covers an entire surface of the display area 13 including the light-shielding film 111, thereby flattening the film surface covering the light-shielding film 111. The light-transmitting film 114 is one exemplary insulating light-transmitting film.

The light-transmitting film 114 can be formed with, for example, a coating-type material. The coating-type material is a material that is applicable in a liquid state. The coating-type material, in a state of being contained in a coating liquid, is spread over a surface on which a film is to be formed, and is cured by a heat treatment or the like, whereby a film of the same is formed. For example, a solution of the coating-type material dissolved in a solvent is dropped on the surface on which a film is to be formed, and the surface is rotated, whereby the coating-type material can be applied on the surface. In this case, the coating-type material is applied so as to reducing protrusions and recesses of the surface. The solvent of the solution thus applied is evaporated by a heat treatment or the like, whereby a film having a flat surface is formed.

As the coating-type material used for forming the light-transmitting film 114, a material for a transparent high-melting-point resin film (polyimide. etc.), a material for an SOG film, or the like, can be used. The SOG film is, for example, a film that is formed with use of a solution obtained by dissolving a silicon compound in an organic solvent. and contains silicon dioxide as a principal component. Examples of a material that can be used for forming the SOG film include: inorganic SOG containing silanol (Si(OH)₄) as a principal component; organic SOG containing silanol having alkyl groups (RₓSi(OH)₄₋ₓ (R: alkyl group)) as a principal component; and a sol-gel material in which an alkoxide of silicon or a metal is used. Examples of inorganic SOG include a hydrogen silsesquioxane (HSQ)-based material. Examples of organic SOG include a methyl silsesquioxane (MSQ)-based material. Examples of the sol-gel material include those containing TEOS (tetraethoxysilane). By applying such a material and firing the same, an SOG film can be formed. Materials for SOG films are not limited to those examples described above. Examples of the method of film forming by coating include spin coating, and slit coating.

By forming the light-transmitting film 114 with a coating-type material, protrusions and recesses formed in the pattern of the light-shielding film 111 can be flattened easily. When the patterning is performed in the process for manufacturing the TFTs 300, therefore, the pooling of liquid such as resist or the like can be eliminated, whereby excellent patterning accuracy can be achieved. In this way, the light-transmitting film 114 can be made a flattening film.

Further, by forming the light-transmitting film 114 with a coating-type material, a sufficient thickness of the light-transmitting film 114 (the thickness of portions thereof on which the light-shielding film 111 is formed) can be ensured easily. For example, the thickness of the light-transmitting film 114 can be increased to about 0.5 to 3 μm. For example, in a case where a material having a low resistance is used for forming the light-shielding film 111, a sufficient distance between the light-shielding film 111 and a conductive film that forms the TFTs 300 (for example, the gate electrodes 301 and the like) can be ensured by the light-transmitting film 114. This makes it possible to prevent parasitic capacitance from being generated between the light-shielding film 111 and electrodes or lines of the TFTs 300.

The third inorganic insulating film 115 is provided so as to cover the light-transmitting film 114.

The second conductive film 140 is provided on the third inorganic insulating film 115. As illustrated in FIG. 8, the second conductive film 140 forms parts of the gate electrode 141, the gate line 16, the source line 15, and the like.

The gate insulating film 116 is provided on the third inorganic insulating film 115 and the second conductive film 140.

The semiconductor film 170 is provided on the gate insulating film 116. The semiconductor film 170 is formed with, for example, an In—Ga—Zn—O-based oxide semiconductor film or the like. The semiconductor film 170 is provided so as to overlap the gate electrode when viewed in a plan view, as illustrated in Figs. S and 10.

The etching stopper film 117 is provided on the gate insulating film 116 and the semiconductor film 170.

In the etching stopper film 117, a first contact hole CH1 that reaches the first conductive film 130 is formed. The first contact hole CH1 passes through the etching stopper film 117, the gate insulating film 116, the third inorganic insulating film 115, the light-transmitting film 114, and the second inorganic insulating film 113. As illustrated in FIG. 8, the first contact hole CH1 is formed, for example, in the vicinity of the source driver 12, in the source line 15. Further, as illustrated in FIG. 8, the first contact hole CH1 is formed in, for example, a connection part of the source line 15 and the source electrode 151.

Further, in the etching stopper film 117, a second contact hole CH2 that reaches the second conductive film 140 is formed. The second contact hole CH2 passes through the etching stopper film 117 and the gate insulating film 116. As illustrated in FIG. 8, the second contact hole CH2 is formed, for example, in the vicinity of the source driver 12, in the source line 15.

The third conductive film 150 is provided on the etching stopper film 117. As illustrated in FIG. 8, the third conductive film 150 forms parts of the source electrode 151, the drain electrode 152, the source line 15, and the like. A part of the third conductive film 150 is formed on the surface of the first contact hole CH1. The third conductive film 150 formed on the surface of the first contact hole CH1 is electrically connected with the first conductive film 130. Besides, a part of the third conductive film 150 is formed on the surface of the second contact hole CH2. The third conductive film 150 formed on the surface of the second contact hole CH2 is electrically connected with the second conductive film 140.

The passivation film 118 is provided on the etching stopper film 117 and the third conductive film 150.

The organic insulating film 119 is provided on the passivation film 118.

As illustrated in FIG. 10, in the organic insulating film 119, a third contact hole CH3 that reaches the fourth conductive film 160 is formed. The third contact hole CH3 passes through the organic insulating film 119 and the passivation film 115. The third contact hole CH3 is formed in, for example, a connection part of the drain electrode 152 and the shutter portion S, as illustrated in FIG. 8.

The fourth conductive film 160 is provided on the organic insulating film 119. A part of the fourth conductive film 160 is formed on the surface of the third contact hole CH3. The fourth conductive film 160 formed on the surface of the third contact hole CH3 is electrically connected with the third conductive film 150.

The fourth inorganic insulating film 120 is provided so as to cover the organic insulating film 119 and the fourth conductive film 160.

### Producing Method

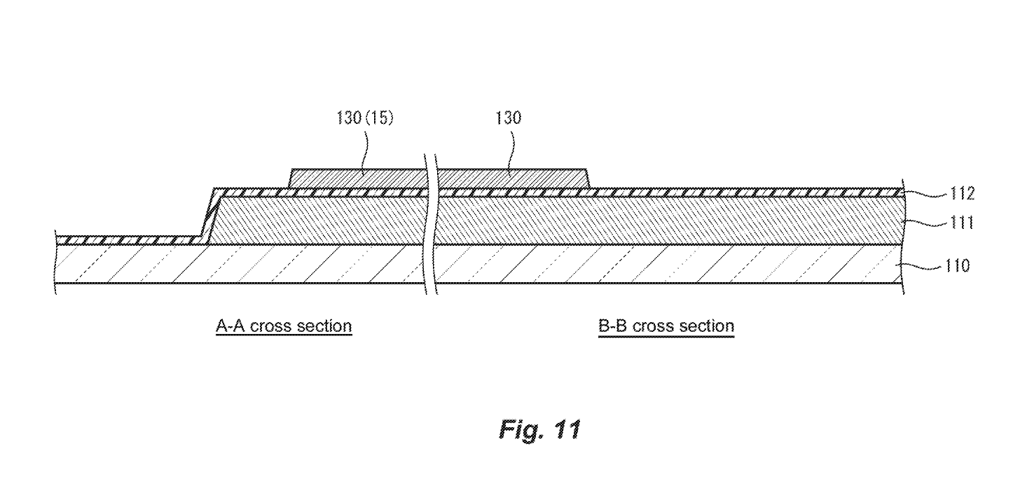

First, the insulating substrate 110 is prepared. Then, as illustrated in FIG. 11, a film for the light-shielding film 111 is formed by using the spin coating method. The film thus formed is fired in an atmosphere at 200 to 350° C. for about one hour, whereby the light-shielding film 111 is formed. The light-shielding film 111 has a thickness of, for example, 0.5 to 3 μm. In place of the spin coating method, the slit coating method may be used for forming the film for the light-shielding film.

Next, as illustrated in FIG. 11, an SiO₂ film is formed on the insulating substrate 110 by using the PECVD method, so as to cover an entire surface of the insulating substrate 110 and the light-shielding film 111, whereby the first inorganic insulating film 112 is formed. The temperature in the film forming is, for example, 200 to 350° C. The SiO₂ film thus obtained has a thickness of, for example, 50 to 200 nm. The first inorganic insulating film 112 is provided for the purpose of improving the adhesiveness with an upper layer film, but the first inorganic insulating film 112 is not an essential constituent member. In a case where, for example, another treatment for improving adhesiveness such as the plasma treatment, the first inorganic insulating film 112 as a constituent member can be omitted.

Next, as illustrated in FIG. 11, a single layer film or a laminate film composed of any of a metal film such as an aluminum (Al) film, a tungsten (W) film, a molybdenum (Mo) film, a tantalum (Ta) film, a chromium (Cr) film, a titanium (Ti) film, a copper (Cu) film, or the like, or a film containing an alloy of any of the foregoing metals, is laminated by sputtering and thereafter patterned, whereby the first conductive film 130 is formed. The first conductive film 130 has a thickness of, for example, 50 nm to 1000 nm.

The first conductive film 130 preferably has a two-layer structure. in the case where the first conductive film 130 has a two-layer structure, a low-resistance metal (for example, aluminum (Al), or copper (Cu)) is suitably used as a material that forms the lower layer. Suitably used as a material that forms the upper layer is a metal that does not tend to be etched during overetching for in-plane distribution in a later dry etching step (for example, titanium (Ti), molybdenum (Mo), titanium nitride (TiN), molybdenum nitride (MoN), or the like).

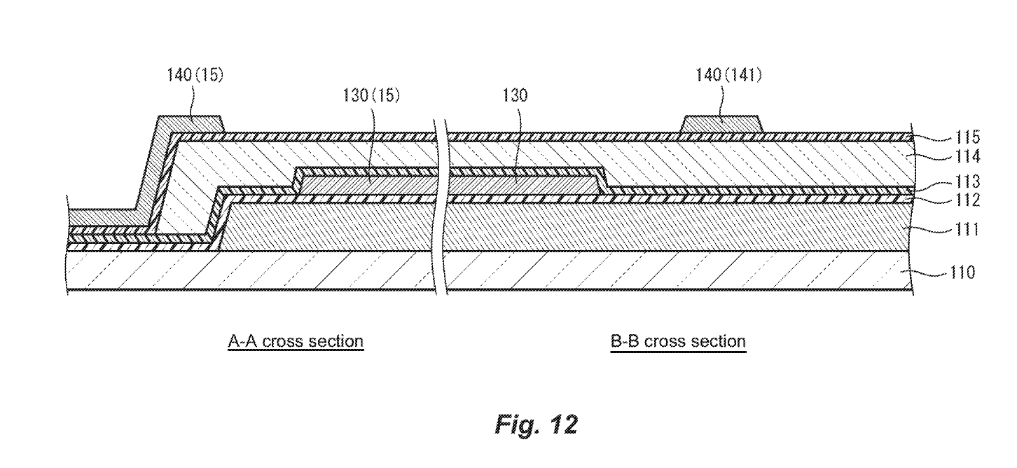

Subsequently, as illustrated in FIG. 12, an SiO₂ film is formed by the PECVD method so as to cover the first inorganic insulating film 112 and the first conductive film 130, whereby the second inorganic insulating film 113 is formed. The temperature during the film formation is, for example, 200° C. to 350° C. The SiO₂ film obtained has a thickness of, for example, 50 nm to 200 nm. The second inorganic insulating film 113 is provided for the purpose of improving the adhesiveness with an upper layer film, but it is not an essential constituent member. For example, in a case where another treatment for improving the adhesiveness such as a plasma treatment is applied, the second inorganic insulating film 113 as a constituent member can be omitted.

Next, as illustrated in FIG. 12, a transparent SOG film having a thickness of about 0.5 to 3 μm is formed by the spin coating method on the second inorganic insulating film 113. The transparent SOG film formed here preferably has a thickness greater than the light-shielding film 111. Then, the film is fired in an atmosphere at 200° C. to 350° C. for about one hour. Then, for example, by performing the patterning with use of a gray tone mask, the transparent SOG film on the peripheral portion of the display area 13 is removed, whereby the light-transmitting film 114 is formed. The light-transmitting film 114 may be formed by the slit coating method, in place of the spin coating method. Further, the light-transmitting film 114 may be formed with, for example, a material having photosensitivity. By forming the light-transmitting film 114 with a material having photosensitivity, the steps of the producing process can be decreased.

Incidentally, by forming the light-transmitting film 114 with a transparent SOG film having a thickness of about 0.5 to 3 μm, the coverage of the first conductive film 130 by the light-transmitting film 114 can be improved. This makes it possible to increase the film thickness of the first conductive film 130 to 500 nm or more. By increasing the film thickness of the first conductive film 130, the taper angle of the first conductive film 130 at the substrate peripheral portion can be decreased, which consequently makes it possible to significantly reduce the line resistance value.

Further, for the purpose of improving the adhesiveness between the transparent SOG film and the third inorganic insulating film 115, and the like, an inorganic insulating film may be formed on the transparent SOG film before the transparent SOG film is patterned.

Next, as illustrated in FIG. 12, an SiO₂ film is formed by the PECVD method so as to cover the light-transmitting film 114. The temperature during the film formation is, for example, 200° C. to 350° C. The obtained SiO₂ film has a thickness of, for example, 50 nm to 200 nm. The SiO₂ film is patterned by photolithography so that the SiO₂ film is patterned in the same pattern as that of the light-transmitting film 114 in the display area 13. More specifically, dry etching is performed by using CF₄ gas and O₂ gas, so that the third inorganic insulating film 115 is formed.

Then, a high-temperature annealing treatment is carried out with respect to the third inorganic insulating film 115 thus formed, in a nitrogen atmosphere. The temperature at which the annealing treatment is carried out is. for example, 400 to 500° C. The annealing time is, for example, about one hour to two hours. The annealing, however, may be carried out in, for example, a clean dry air (CDA) atmosphere, in place of the nitrogen atmosphere. By performing the annealing treatment with respect to the light-transmitting film 114 preliminarily, the occurrence of cracks in the light-transmitting film 114, or the occurrence of peeling-off of the third inorganic insulating film 115, in a later high-temperature annealing step in the TFT manufacturing process can be suppressed.

The temperature of the above-described high-temperature annealing treatment is preferably equal to or higher than the treatment temperature in a later step of manufacturing the TFTs 300 (the temperature in the film formation by CVD, or the annealing temperature). By performing the high-temperature annealing treatment at a temperature equal to or higher than the treatment temperature in the TFT 300 manufacturing process, moisture and the like contained in the light-transmitting film 114 can be removed. This makes it possible to prevent such a problem that moisture contained in the light-transmitting film 114 would ooze out to the TFTs 300 after the TFTs 300 are formed and cause defects in the TFTs 300.

Next, as illustrated in FIG. 12, a single layer film or a laminate film composed of any of a metal film such as an aluminum (Al) film, a tungsten (W) film, a molybdenum (Mo) film, a tantalum (Ta) film, a chromium (Cr) film, a titanium (Ti) film, a copper (Cu) film, or the like, or a film containing an alloy of any of the foregoing metals, is laminated by sputtering and thereafter patterned, whereby the second conductive film 140 is formed. The second conductive film 140 has a thickness of, for example, 50 nm to 500 nm. Here, parts of the gate electrodes 141, the source lines 15, and the like are formed.

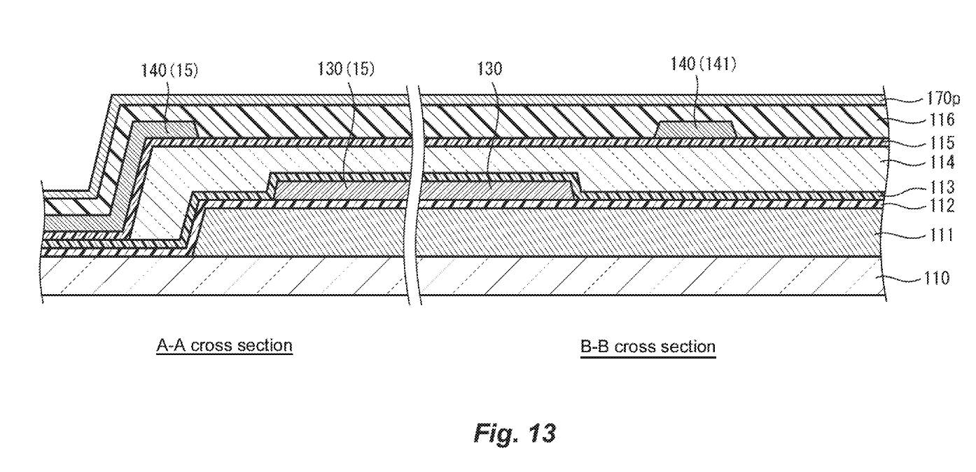

Next, as illustrated in FIG. 13, an SiNₓ film is formed on the third inorganic insulating film 205 by using the PECVD method, so as to cover the second conductive film 140, whereby the gate insulating film 116 is formed. The obtained gate insulating film 116 has a thickness of, for example 100 to 500 nm. The gate insulating film 116 may be a silicon system inorganic film (SiO₂ film or the like) containing oxygen, or a laminate film of an SiO₂ film and an SiNₓ film.

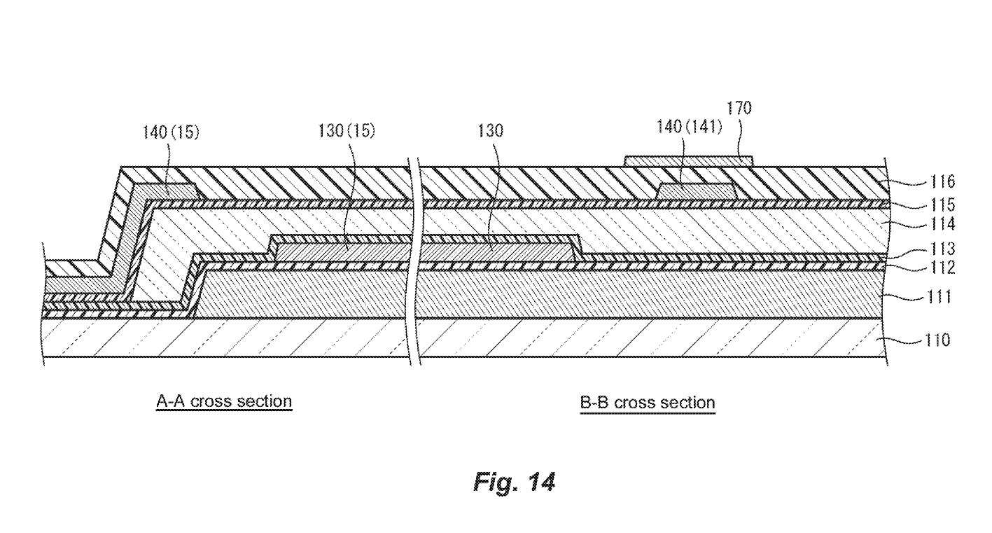

Next, as illustrated in FIG. 13, a film 170p made of an oxide semiconductor is formed on the gate insulating film 116 by using, for example, the sputtering method. Then, a high-temperature annealing treatment is performed with respect to the film 170p thus formed, under a nitrogen atmosphere. The temperature at which the high-temperature annealing treatment is performed is, for example, 400 to 500° C. The annealing time is, for example, about one hour to two hours. The annealing, however, may be carried out in, for example, a clean dry air (CDA) atmosphere, in place of the nitrogen atmosphere. After annealing, as illustrated in FIG. 14, the film 170p is patterned so that the semiconductor films 170 are formed in areas corresponding to the gate electrodes 141.

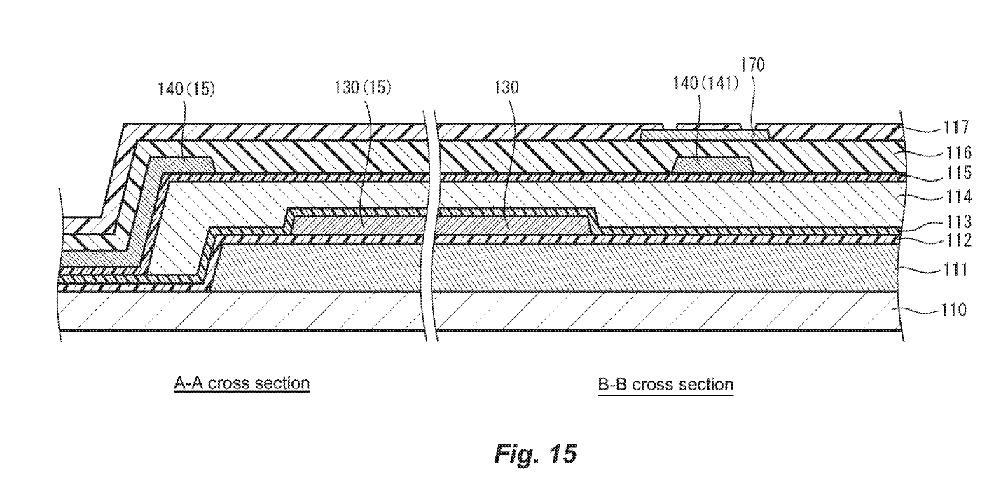

Next, as illustrated in FIG. 15, an SiO₂ film is formed by using the PECVD method, so as to cover the gate insulating film 116 and the semiconductor film 170, whereby the etching stopper film 117 is formed. The etching stopper film 117 thus obtained has a thickness of, for example, 100 to 500 nm.

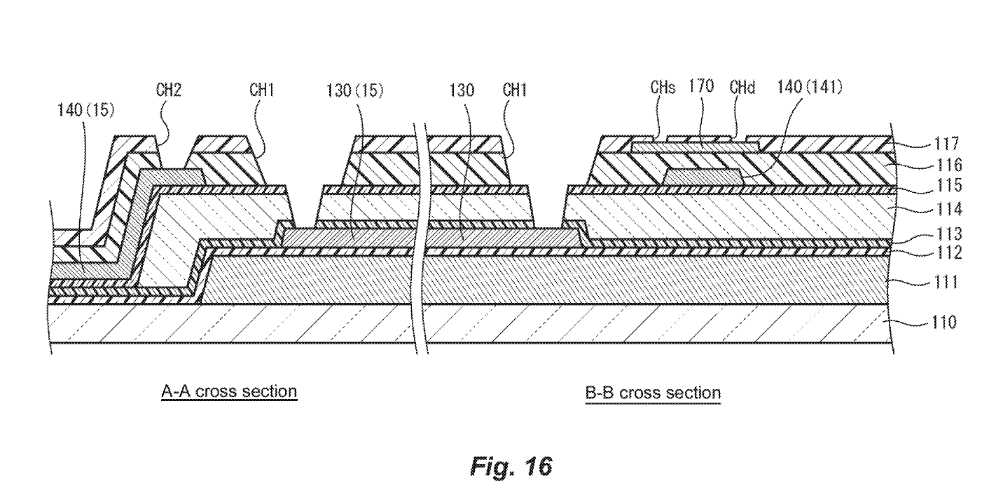

Subsequently, as illustrated in FIG. 16, contact holes CHs, CHd that allow the source electrode 151 and the drain electrode 152 of the TFT 300 to reach the semiconductor film 170 are formed. Further, the first contact hole CH1 that allows the first conductive film 130 and the third conductive film 150 to be connected to each other, and the second contact hole CH2 that allows the second conductive film 140 and the third conductive film 150 to be connected to each other, are formed.

More specifically, first, a resist is applied over the etching stopper film 117. Then, after photolithography is performed, the etching stopper film 117 and the gate insulating film 116 are etched, whereby the contact holes CHs, CHd are formed. Here, at bottoms of the contact holes CHs, CHd, the source electrode 151 and the drain electrode 152 are exposed, respectively. Further, at the same time as this, a part of the first contact hole CH1 and the second contact hole CH2 are formed. Subsequently, the resist is stripped off, whereby the second conductive film 140 is exposed at the bottom of the second contact hole CH2.

Subsequently, again, a resist is applied, subjected to photolithography, and thereafter dried, whereby a hole that passes through the third inorganic insulating film 115, the light-transmitting film 114, and the second inorganic insulating film 113 is formed. Thereby, the first contact hole CH1 is formed. Then, the resist is stripped off. Here, at the bottom of the first contact hole CH1, the first conductive film 130 is exposed.

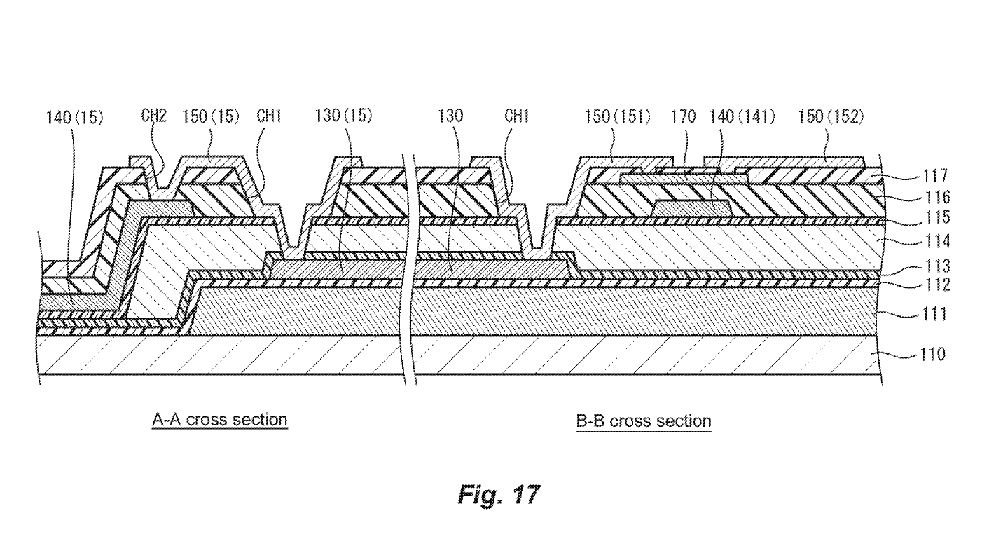

Subsequently, as illustrated in FIG. 17, a single layer film or a laminate film composed of any of a metal film such as an aluminum (Al) film, a tungsten (W) film, a molybdenum (Mo) film, a tantalum (Ta) film, a chromium (Cr) film, a titanium (Ti) film, a copper (Cu) film, or the like, or a film containing an alloy of any of the foregoing metals, is laminated on the etching stopper film 117 by the sputtering method, whereby the third conductive film 150 is formed. Then, the third conductive film 150 is patterned by photolithography, whereby parts of the source electrode 151, the drain electrode 152, the source line 15, and the like, are formed. The third conductive film 150 has a thickness of, for example, 50 to 500 nm. Here, in the first contact hole CH1, the third conductive film 150 and the first conductive film 130 are electrically connected. Further, in the second contact hole CH2, the third conductive film 150 and the second conductive film 140 are electrically connected. In the first contact hole CH1, the first conductive film 130 and the third conductive film 150 are in direct contact with each other thereby being electrically connected, and in the second contact hole CH2, the second conductive film 140 and the third conductive film 150 are in direct contact with each other thereby being electrically connected, whereby the first conductive film 130 and the second conductive film 140 are electrically connected with each other via the third conductive film 150. In other words, the first conductive film 130 and the second conductive film 140 are not in direct contact with each other.

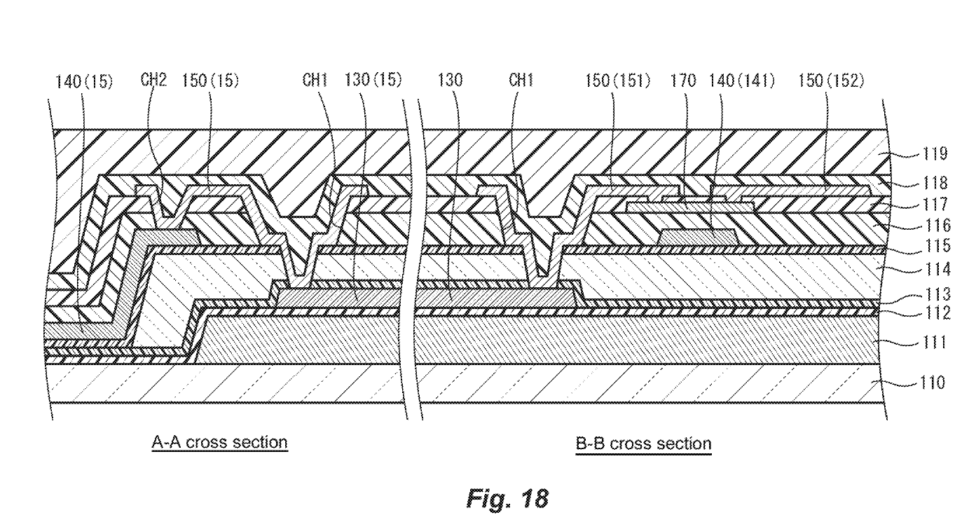

Next, as illustrated in FIG. 18, an SiO₂ film is formed by using the PECVD method so as to cover the etching stopper film 117 and the third conductive film 150, whereby the passivation film 118 is formed. The SiO₂ film has a thickness of, for example, 100 to 500 nm.

Next, as illustrated in FIG. 18, a photosensitive resin film is formed on the passivation film 118 by using the spinning method, whereby the organic insulating film 119 is formed. Here, the organic insulating film 119 formed has a thickness of, for example, 0.5 to 3 μm.

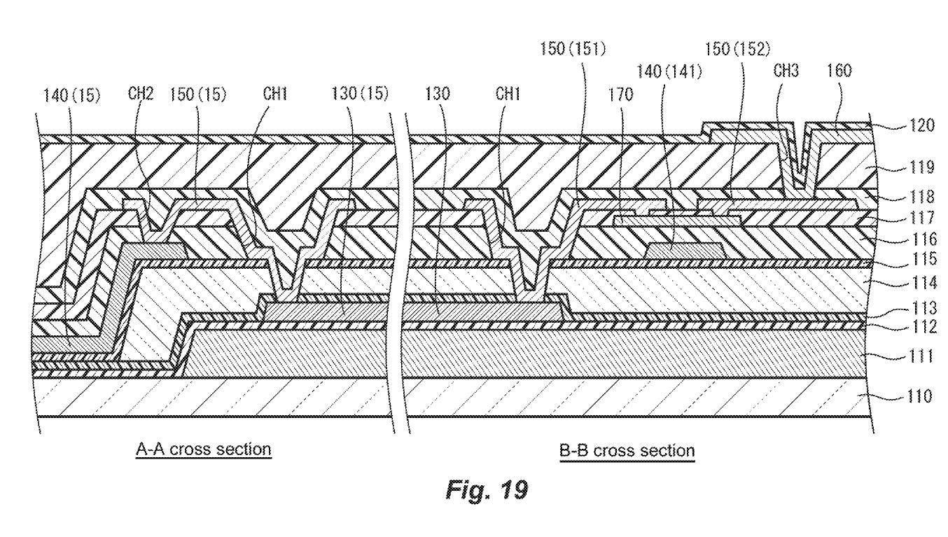

Subsequently, as illustrated in FIG. 19, the third contact hole CH3 is formed. The third contact hole CH3 is formed above the drain electrode 152. At the bottom of the third contact hole CH3, the third conductive film 150 (drain electrode 152) is exposed.

Subsequently, as illustrated in FIG. 19, a single layer film or a laminate film composed of any of a metal film such as an aluminum (Al) film, a tungsten (W) film, a molybdenum (Mo) film, a tantalum (Ta) film, a chromium (Cr) film, a titanium (Ti) film, a copper (Cu) film, or the like, or a film containing an alloy of any of the foregoing metals, is laminated by sputtering. Then, this laminated body is patterned by photolithography, whereby the fourth conductive film 160 is formed. Here, in the third contact hole CH3, the fourth conductive film 160 and the drain electrode 152 are electrically connected.

Next, as illustrated in FIG. 19, an SiN_{X} film or an SiO₂ film is formed on the organic insulating film 119 by using the PECVD so as to cover the fourth conductive film 160, whereby the fourth inorganic insulating film 120 is formed. The fourth inorganic insulating film 120 thus obtained has a thickness of, for example, 100 to 500 nm.

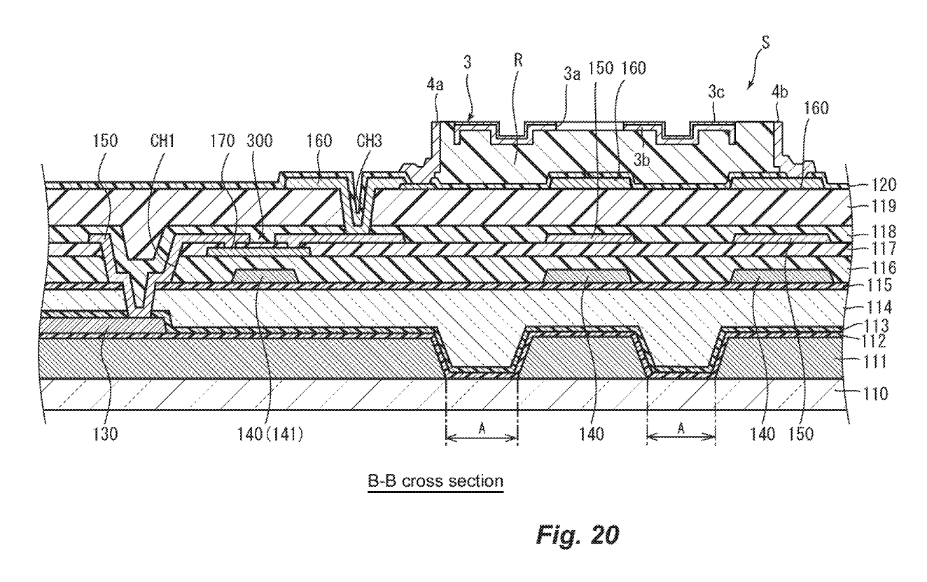

Next, the shutter body 3 is formed. First, as illustrated in FIG. 20, a resist R is applied to an area including at least the light-transmitting area A, by using, for example, the spin coating method.

Next, as illustrated in FIG. 20, an amorphous silicon (a-Si) layer is formed by the PECVD method so as to cover the resist R. Here, the film is formed so as to cover both of the upper surface and the side surfaces of the resist R. The a-Si layer formed has a thickness of, for example, 200 to 500 nm. Then, the a-Si layer is patterned by photolithography, whereby the first electrode portion 4a, the second electrode portion 4b, the shutter beam 5 (not illustrated in FIG. 20), and the shutter main body 3b are formed. The first electrode portion 4a and the second electrode portion 4b are composed of portions of the a-Si layer formed on a side surface of the resist R.

Subsequently, as illustrated in FIG. 20, the metal film 3c is provided in an upper layer with respect to the shutter main body 3b. The metal film 3c is formed by, for example, laminating a metal film such as an aluminum (Al) film, a tungsten (W) film, a molybdenum (Mo) film, a tantalum (Ta) film, a chromium (Cr) film, a titanium (Ti) film, or a copper (Cu) film, or alternatively, laminating a film containing an alloy of any of the foregoing metals, by the sputtering method. Thereby, the shutter body 3 is formed.

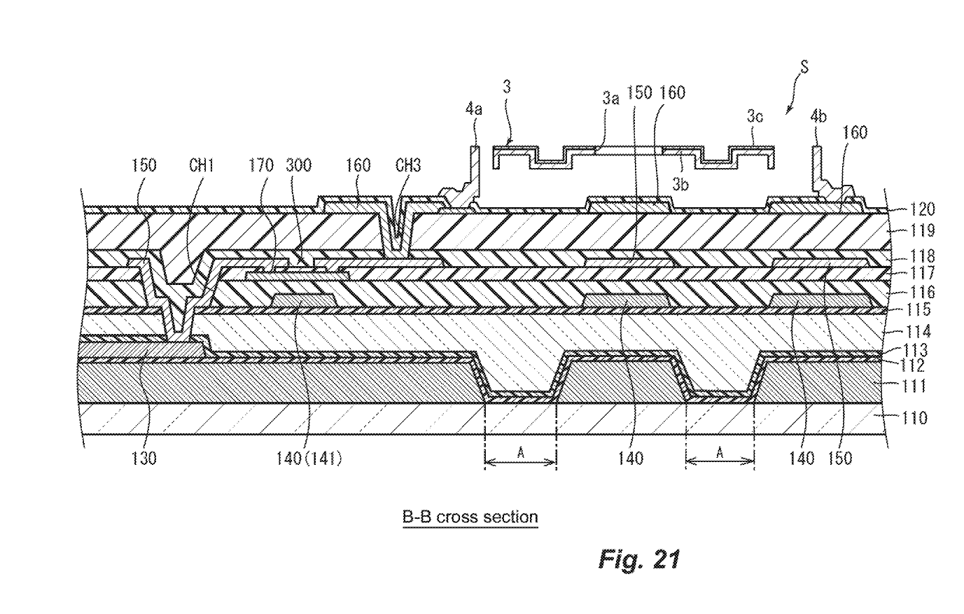

Finally, as illustrated in FIG. 21, the resist R is stripped off by the spinning method. This causes the shutter body 3 to be arranged in a state of being floated from the fourth inorganic insulating film 120, with a space therebetween. The shutter body 3 is supported by the shutter beam anchors 8, via the shutter beams 5.

Through the above-described steps, the first substrate 11 is produced.

### Effects of Embodiment

In the first substrate 11 of the present embodiment, the first conductive film 130 and the second conductive film 140 are electrically connected through the third conductive film 150. In other words, the first conductive film 130 and the third conductive film 150 are electrically connected through the first contact hole CH1, and further, the second conductive film 140 and the third conductive film 150 are electrically connected through the second contact hole CH2. This makes it unnecessary to provide a contact hole in the light-transmitting film 114 so as to bring the first conductive film 130 and the second conductive film 140 into direct contact for the purpose of electrically connecting the first conductive film 130 and the second conductive film 140. This therefore makes it unnecessary to form a contact hole in the light-transmitting film 114 before forming the second conductive film 140.

Since it is unnecessary to form a contact hole in the light-transmitting film 114 before forming the second conductive film 140, it is possible to form the third inorganic insulating film 115 and the semiconductor film 170 in a state in which any contact hole is not formed in the light-transmitting film 114. In other words, in a state in which no contact hole is formed in the light-transmitting film 114, the semiconductor film 170 can be subjected to a high-temperature annealing treatment. In a case of an active matrix substrate having such a configuration that a first conductive film and a second conductive film are in direct contact thereby being electrically connected in a contact hole formed in a light-transmitting film, the contact hole has been already formed in the light-transmitting film when a semiconductor film is subjected to a high-temperature annealing treatment. During the high-temperature annealing treatment, therefore, cracks tend to occur in the contact hole in the light-transmitting film, and as a result, a contact failure occurs between the first the conductive film and the second conductive film in some cases. In the case of the first substrate 11 of the present embodiment, however, the semiconductor film 170 is subjected to a high-temperature annealing treatment in a state in which no contact hole is formed in the light-transmitting film 114, and accordingly the occurrence of cracks to the light-transmitting film 114 is suppressed, thereby resulting in that such a contact failure can be suppressed. As a result, the yield and reliability of the first substrate 11 can be improved.

### Modification Example of Embodiment 1

Embodiment 1 is described with reference to an example in which the first contact hole CH1, partially, and the second contact hole CH2 are simultaneously formed, and thereafter, the light-transmitting film 114 is etched so that the first contact hole CH1 is formed (in other words, the first contact hole CH1 is formed through two operations of photolithography). The first contact hole CH1 and the second contact hole CH2, however, may be simultaneously formed through one operation of photolithography, by forming the second conductive film 140 with a titanium (Ti) film, a molybdenum (Mo) film, or alternatively, a nitrided titanium (Ti) film or a nitrided molybdenum (Mo) film, which has a high etching resistance.

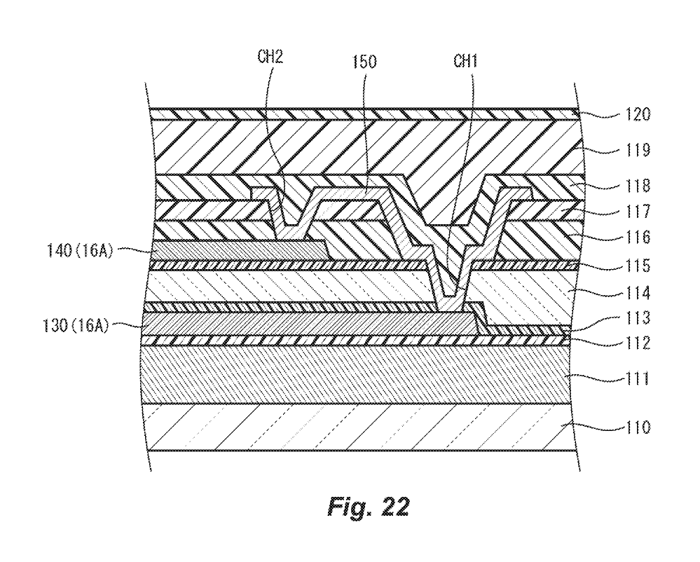

Embodiment 1 is described with reference to FIG. 8 as an exemplary line arrangement on the first substrate 11, but this is a merely one example of the present invention. For example, the configuration of the first substrate may be such that, as illustrated in FIG. 22, the gate line 16A and the first conductive film 130, formed with the second conductive films 140, overlap with each other when viewed in the direction vertical to the substrate. In this case, the gate line 16A is electrically connected with the first conductive film 130 through the third conductive film 150. With this configuration of the first substrate, the gate line 16A can be designed so as to be thinner, whereby a display device with a higher aperture ratio can be provided.

Further, as the present invention, a configuration is described in which the gate line 16 is connected with the first conductive film though the third conductive film, but the present invention can be applied to a line formed with the second conductive film such as a capacitor line or the like, in addition to the gate line 16. Still further, the configuration may be such that the source line 15 inside a pixel is formed with the third conductive film 150, and the source line in the vicinity of the source driver 12 is formed with the first conductive film 130.

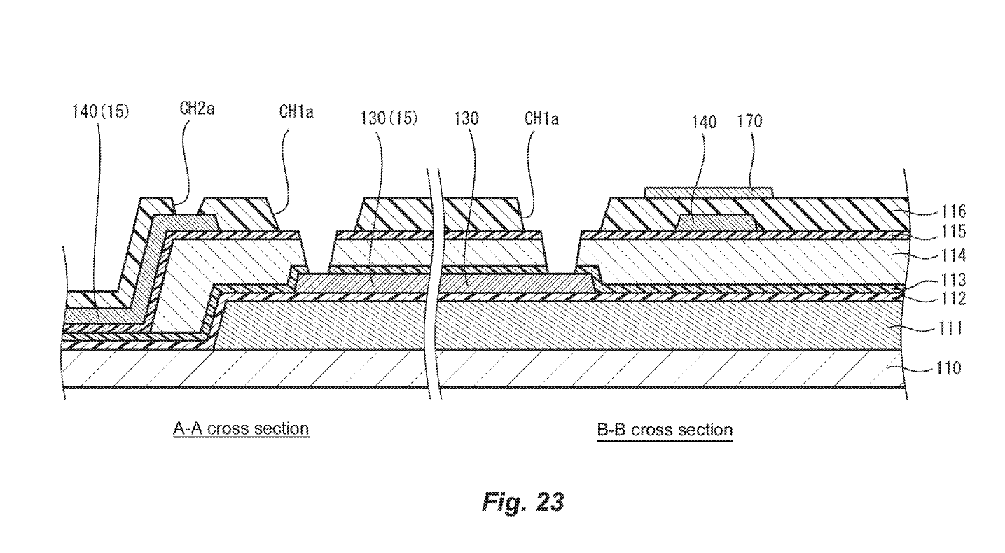

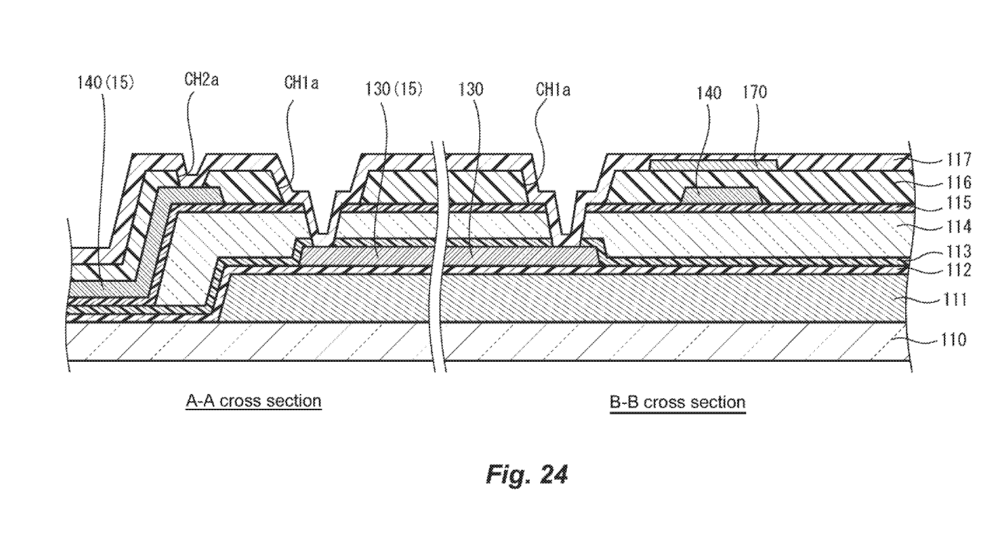

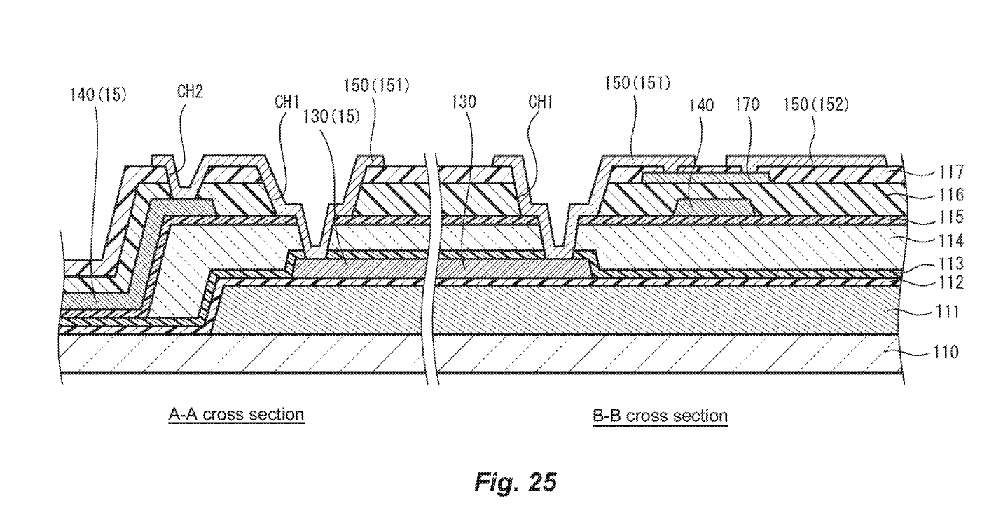

Embodiment 1 is described with reference to an example in which after the gate insulating film 116 and the etching stopper film 117 are formed, these are etched, whereby the second contact hole CH2 is formed, but the present invention is not limited to this. For example, as illustrated in FIG. 23, after the semiconductor film 170 is subjected to the high-temperature annealing treatment, the gate insulating film 116 and the light-transmitting film 114 may be etched before the etching stopper film 117 is formed, so that a part CH1a of the first contact hole CH1, and a part CH2a of the second contact hole CH2, are formed. After this, as illustrated in FIG. 24, the etching stopper film 117 is formed, and further, as illustrated in FIG. 25, the etching stopper film 117 is etched. whereby the first contact hole CH1 and the second contact hole CH2 can be formed.

The first substrate 11 of the present embodiment is described with reference to an example in which the first conductive film 130 is formed on the light-shielding film 111, but the configuration may be such that the first conductive film 130 is formed on the insulating substrate 110, and the light-shielding film 111 is formed so as to cover the insulating substrate 110 and the first conductive film 130. In this case, in order to prevent light from the insulating substrate 110 side, incident on the first substrate 11, from being reflected on the first conductive film 130, a reflection prevention film is preferably provided in a lower layer with respect to the first conductive film 130.

The active matrix substrate of the present embodiment is described with reference to an exemplary configuration including the etching stopper film 117, but the etching stopper film 117 is not an essential member. In this case, the TFTs formed on the active matrix substrate are of channel-etch type in which the etching stopper film is omitted.

### Embodiment 2

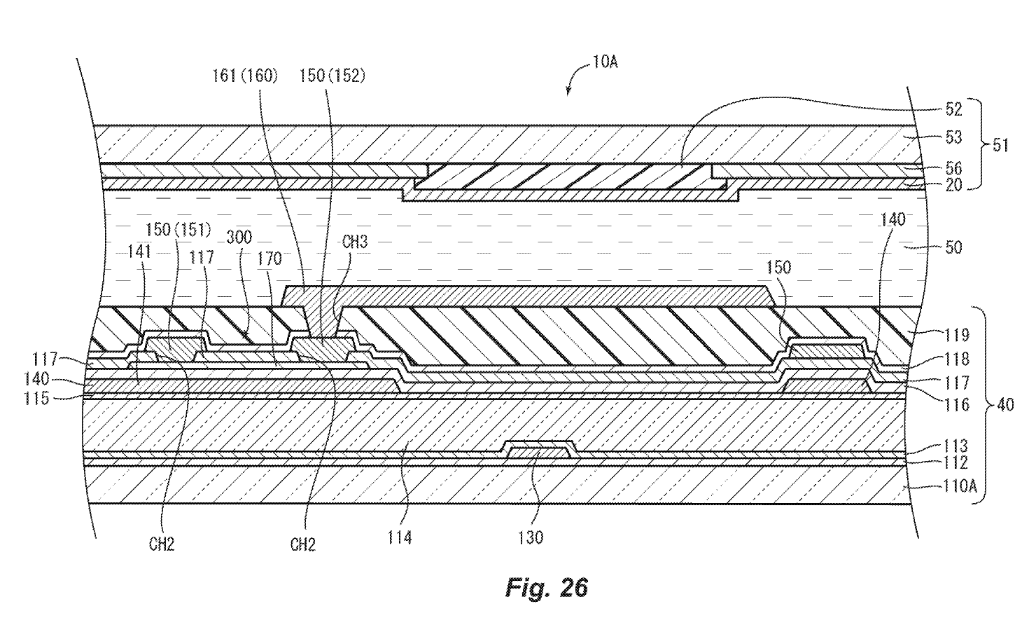

FIG. 26 is a cross-sectional view illustrating an exemplary configuration of a display device in Embodiment 2. A display device 10A illustrated in FIG. 26 is a liquid crystal display device. The display device 10A includes an active matrix substrate 40 on which TFTs 300 are arranged, a counter substrate 51 opposed to the active matrix substrate 40, and a liquid crystal layer 50 sealed between the active matrix substrate 40 and the counter substrate 51. On a side of the active matrix substrate 40 opposite to the liquid crystal layer 50, a backlight (not shown) is arranged.

The active matrix substrate 40 includes a substrate 110A (an exemplary insulating substrate). On the substrate 110A, a first inorganic insulating film 112 is provided that covers the surface of the substrate 110A. On the first inorganic insulating film 112, the following are laminated: a second inorganic insulating film 113; a light-transmitting film 114; a third inorganic insulating film 115; a gate insulating film 116; a semiconductor film 170; an etching stopper film 117; a passivation film 118; and an organic insulating film 119. These layers can be formed in the same manner as that in Embodiment 1 described above.

Between the first inorganic insulating film 112 and the second inorganic insulating film 113, a first conductive film 130 is formed. On the light-transmitting film 114, a second conductive film 140 is formed, with the third inorganic insulating film 115 being interposed therebetween. The second conductive film 140 includes a gate electrode 141 of the TFT 300. Between the etching stopper film 117 and the passivation film 118, a third conductive film 150 is formed. The third conductive film 150 includes a source electrode 151 and a drain electrode 152 of the TFT 300. The TFT 300 can have the same configuration as that of Embodiment 1.

The TFT 300 including the source electrode 151 and the drain electrode 152 is covered with a passivation film 118. The passivation film 118 is further covered with an organic insulating film 119. In the passivation film 118 and the organic insulating film 119, a contact hole CH3 is provided that reaches the drain electrode 152. On the organic insulating film 119, a pixel electrode 161 is formed. A part of the pixel electrode 161 is provided so as to cover the surface of the contact hole CH3, and is electrically connected with the drain electrode 152. The pixel electrode 161 is formed with a fourth conductive film 160. In the active matrix substrate 40, other members may be provided, in addition to the members illustrated in FIG. 26; for example, a light distribution film and a polarization film provided so as to be in contact with the liquid crystal layer 50 may be provided.

The counter substrate 51 includes a substrate 53, as illustrated in FIG. 26. On the substrate 53, color filters 52, a counter electrode (common electrode) 20, and a black matrix 56 are arranged. On the counter substrate 51, the counter electrode 20 is provided at a position opposed to the pixel electrodes 161 with the liquid crystal layer 50 being interposed therebetween. Further, the color filter layers 52 are arranged at positions corresponding to the pixels, respectively. At positions surrounding the pixels. the black matrix 56 is arranged. In other words, at positions corresponding to portions of the boundaries between adjacent ones of the pixels, the black matrix 56 is provided. More specifically, the black matrix 56 is provided in an area that is superposed on the source lines 15 and the gate lines 16 when viewed in a direction vertical to the substrate 110A. Further, the black matrix 56 may be provided in an area that is superposed on the TFTs 400. On the counter substrate 51, other members may be provided, in addition to the members illustrated in FIG. 26; for example, a light distribution film and a polarization film that are provided in contact with the liquid crystal layer 50, and the like, may be provided.

The light-transmitting film 114 can be formed with, for example, a coating-type material. As the coating-type material, the same material as the coating-type material in Embodiment 1 can be used. Forming the light-transmitting film 114 with a coating-type material, such as an SOG film or the like, makes it easier to increase the film thickness of the light-transmitting film 114.

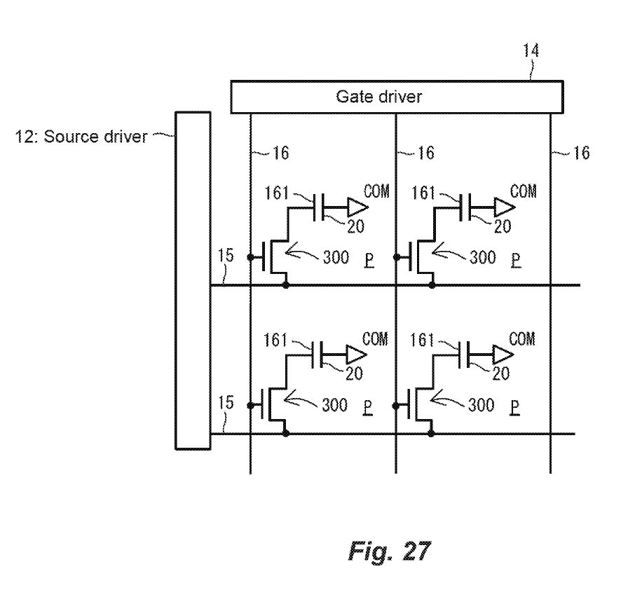

FIG. 27 illustrates an exemplary configuration of the display device 10A illustrated in FIG. 26. In the example illustrated in FIG. 27, a plurality of gate lines 16, and a plurality of source lines 15 arrayed so as to intersect with the gate lines 16 are provided in the display device 10A. The gate lines 16 are connected to the gate driver 14, and the source lines 15 are connected to the source driver 12. The source lines 15 are formed with, for example, the third conductive films 150.

The gate line 16 can be formed with, for example, the first conductive film 130 and the second conductive film 140. Forming the gate line 16 with the first conductive film 130 and the second conductive film 140 makes it possible to reduce the width of the gate line, thereby achieving a higher resolution. The first conductive film 130 and the second conductive film 140, composing the gate line 16, are not in direct contact with each other. The first conductive film 130 and the second conductive film 140 are electrically connected with each other via the third conductive film 150. In other words, as is the case with Embodiment 1, the first conductive film 130 and the third conductive film 150 are connected via the first contact hole CH1. Further, the third conductive film 150 and the second conductive film 140 are connected via the second contact hole CH2.

Incidentally, the capacitor line and the gate line 16 can be formed a conductive film different from the conductive film used in the above-described example.

Further, as is the case with Embodiment 1, the configuration may be as follows: in the display area, the source line 15 is formed with the first conductive film 130, and in the vicinity of the source driver 12, the source line 15 formed with the first conductive film 130 is electrically connected with the second conductive film 140 via the third conductive film 150.

At points of intersection of these source lines 15 and gate lines 16, pixels P are provided, respectively. In each pixel P, a TFT 300, and a pixel electrode 161 connected to the TFT 300, are included. The gate lines 16 are connected to the gates of the TFTs 300, the source lines 15 are connected to the sources of the TFTs 300, and the pixel electrodes 161 are connected to the drains of the TFTs 300. In this way, in the display device 10A, a plurality of areas of the pixel P are formed in the areas defined in matrix by the source lines 15 and the gate lines 16. In the display device 10A, an area where the pixels P are formed is the display area.

### Effects of Embodiment 2

In the display device 10A of the present embodiment, in the gate line 16, the first conductive film 130 and the second conductive film 140 are connected via the third conductive film 150. In other words, it is unnecessary to bring the first conductive film 130 and the second conductive film 140 into direct contact with each other in order to electrically connect the first conductive film 130 and the second conductive film 140, and it is unnecessary to form a contact hole in the light-transmitting film 114 before forming the second conductive film 140.

Since it is unnecessary to form a contact hole in the light-transmitting film 114 before forming the second conductive film 140, the third inorganic insulating film 115 and the semiconductor film 170 can be formed in a state in which no contact hole is formed in the light-transmitting film 114. In other words, in a state in which no contact hole is formed in the light-transmitting film 114, the semiconductor film 170 can be subjected to a high-temperature annealing treatment. When the semiconductor film 170 is annealed, therefore. the light-transmitting film 114 has no contact hole therein and hence it is flat. This makes it possible to prevent cracks from occurring to the light-transmitting film 114 due to heat during the high-temperature annealing treatment with respect to the semiconductor film 170. As a result, the yield and reliability of the active matrix substrate 40 can be improved.

### Modification Example of Embodiment 2

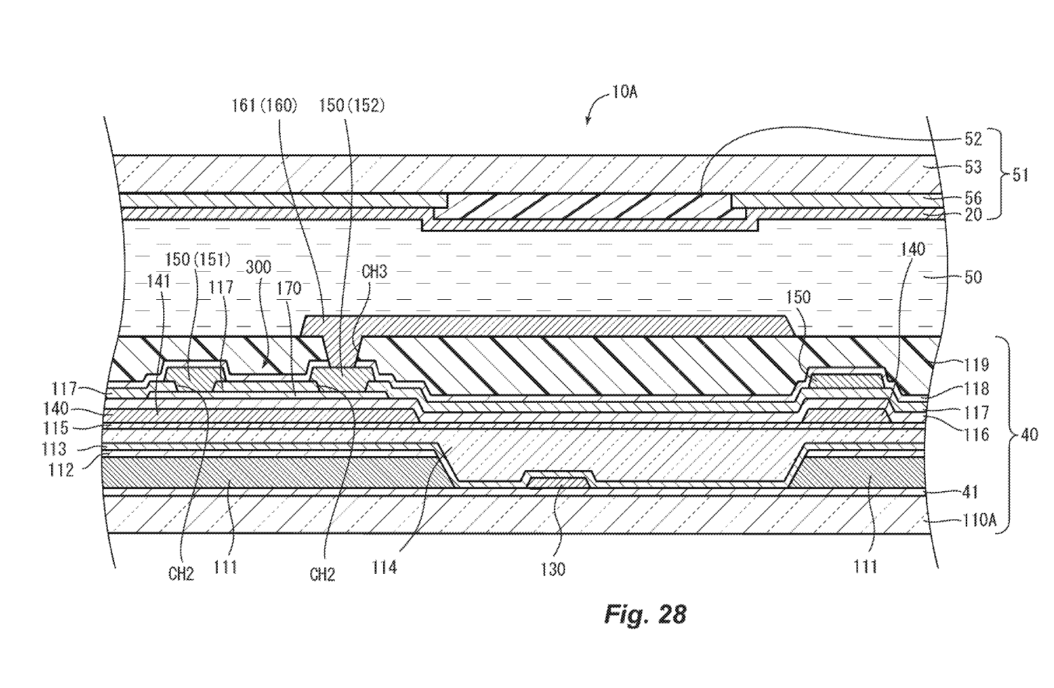

The above-described configuration may further include a light-shielding film 111 in a lower layer with respect to the first inorganic insulating film 112, as illustrated in FIG. 28. In this case, on the surface of the substrate 110A, a surface coating film 41 is formed. In the case where the active matrix substrate 40 includes the light-shielding film 111, this active matrix substrate 40 can compose, for example. a see-through-type liquid crystal display that allows an object that is present on the back side of the liquid crystal display to be seen through the liquid crystal display. This is because, in the see-through-type liquid crystal display, it is useful to form the light-shielding layer on the display viewing side of conductive films, in order to prevent external light advancing from the display viewing side into the display device from being reflected on the conductive films such as gate electrodes.

In the active matrix substrate 40, the light-shielding film 111 can be provided in an area superposed on the black matrix 56 of the counter substrate 51, when viewed in a direction vertical to the substrate. For example, the light-shielding film 111 can be provided in an area that is superposed on the source lines 15 and the gate lines 16. Alternatively, the light-shielding film 111 can be provided in an area superposed on the TFTs 300. This makes it possible to prevent light incident through the substrate 110A from being reflected on metals of the TFTs 300 or lines. Consequently, the display quality is improved.

The light-transmitting film 114 can be formed with, for example, a coating-type material. As the coating-type material, the same coating-type material as that in Embodiment 1 can be used. Forming the light-transmitting film 114 with a coating-type material such as an SOG film or the like makes it easy to form the light-transmitting film 114 having a greater film thickness. Accordingly, in a case where, for example, the light-shielding film 111 is formed with a material having a low resistance, parasitic capacitance can be prevented from being generated between the light-shielding film 111 and the second conductive film 140 on the light-transmitting film 114. Further, by forming the light-transmitting film 114 with a coating-type material, steps formed by the light-shielding film 111 can be reduced. This makes it easier to flatten the surface of a film covering the light-shielding film 111.

### Embodiment 3

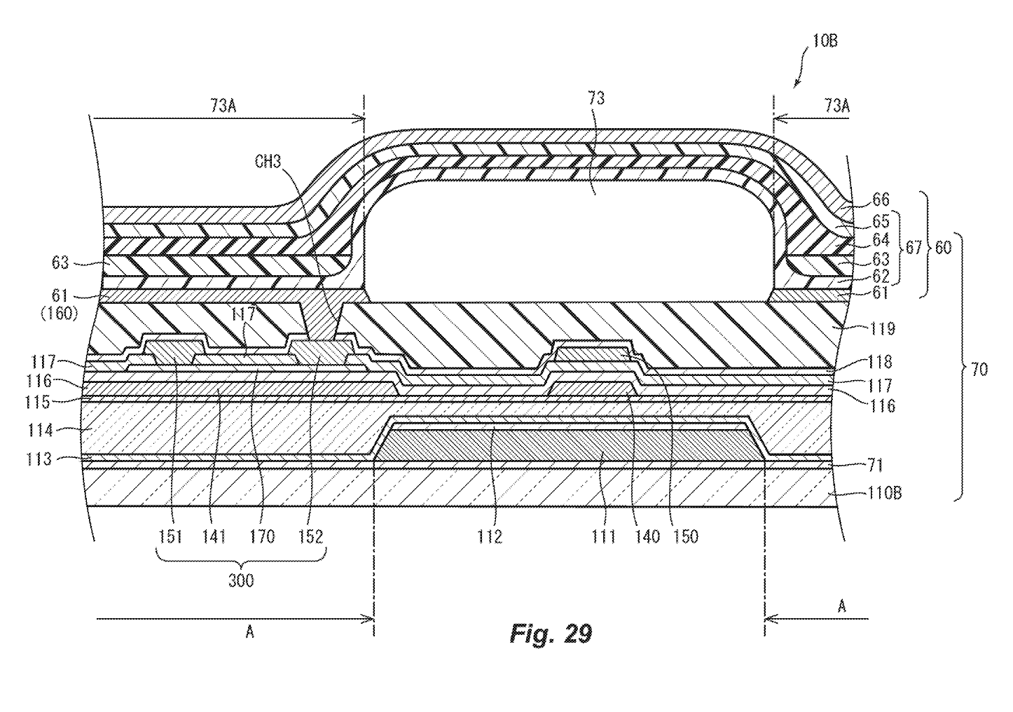

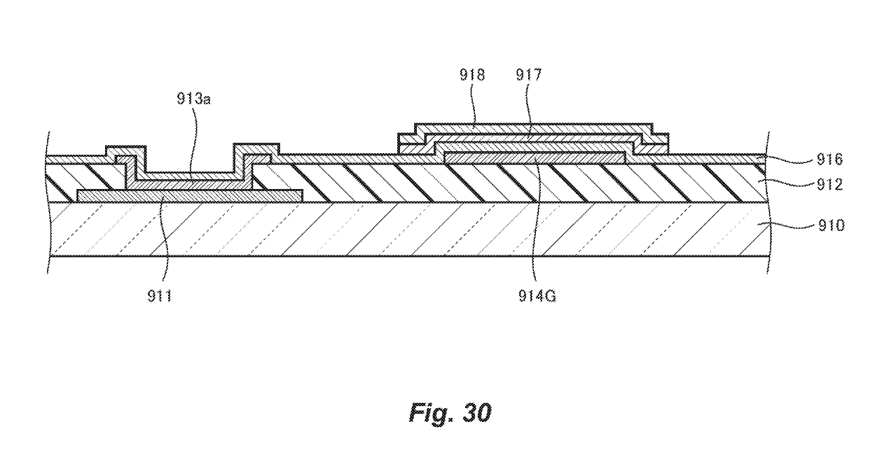

FIG. 29 is a cross-sectional view illustrating an exemplary configuration of a display device in Embodiment 3. A display device 10B illustrated in FIG. 29 is a bottom emission type organic electroluminescence display (organic EL display). The display device 10B includes an active matrix substrate 70. The active matrix substrate 70 includes a substrate 111B (an exemplary insulating substrate), TFTs 300 arranged in matrix on the substrate 111B, and organic EL elements 60 connected to the TFTs 300. Further, though not illustrated. an enclosure substrate is provided so as to be opposed to the substrate 110B, with an adhesive layer covering the organic EL elements 60 being interposed therebetween. With this, the organic EL elements 60 are enclosed between the substrate 110E and the enclosure substrate.

The active matrix substrate 70 includes a substrate 110E (an exemplary insulating substrate). On the substrate 110B, a surface coating film 71 is provided that covers the surface of the substrate 1108. On the surface coating film 71, the following are laminated: a light-shielding film 111; a first inorganic insulating film 112; a second inorganic insulating film 113: a light-transmitting film 114; a third inorganic insulating film 115; a gate insulating film 116; a semiconductor film 170; an etching stopper film 117; a passivation film 118; and an organic insulating film 119. These layers can be formed in the same manner as that in Embodiments 1 and 2 described above.

Though not illustrated, a plurality of gate lines, and a plurality of source lines that intersect with the gate lines are provided in an upper layer with respect to the light-transmitting film 114. A gate line driving circuit for driving the gate lines are connected to the gate lines, and a signal line driving circuit for driving the source lines are connected to the source lines. Pixels are arranged at positions corresponding to points of intersection between the gate lines and the source lines, respectively. At the pixels, the TFTs 300 connected to the gate lines and the source lines are arranged, respectively. The pixels are arranged in matrix. The pixels include pixels emitting light of red (R), pixels emitting light of blue (B), and pixels emitting light of green (G).

In the fourth inorganic insulating film 120 and the organic insulating film 119, a contact hole CH3 reaching the drain electrode 152 is formed. A first electrode 61 of the organic EL element 60 is formed on the organic insulating film 119. A part of the first electrode 61 is provided so as to cover the surface of the contact hole CH3, and is electrically connected to the drain electrode 152. The first electrode 61 can be formed with, for example, a fourth conductive film 160.

An edge cover 73 is formed so as to cover an end of the first electrode 61 on the organic insulating film 119. The edge cover 73 is an insulating layer for preventing the first electrode 61 and the second electrode 66 from becoming short-circuited due to a decrease in the thickness of the organic EL layer 67, the occurrence of electric field concentration, or the like at the end of the first electrode 61.

In the edge cover 73, an opening 73A is provided for each pixel. The opening 73A of the edge cover 73 is a light emission area of each pixel. In other words, the pixels are separated from one another by the edge cover 73 having insulating properties. The edge cover 73 functions as an element separation film.

The organic EL element 20 is a light emitting element that is capable of performing high-luminance light emission with low-voltage direct-current driving, and includes a first electrode 61, an organic EL layer 67, and a second electrode 66 in this order. The first electrode 61 is a layer that has a function of injecting (supplying) holes into the organic EL layer 67.

The organic EL layer 27 includes a hole injection layer-cum-hole transport layer 62, a light emission layer 63, an electron transport layer 64, and an electron injection layer 65, in the stated order from the first electrode 61 side, between the first electrode 61 and the second electrode 66. In the present embodiment, the first electrode 61 is an anode and the second electrode 66 is a cathode, but the configuration may be such that the first electrode 61 is a cathode and the second electrode 66 is an anode.

The hole injection layer-cum-hole transport layer 62 has both a function as a hole injection layer and a function as a hole transport layer. The hole injection layer-cum-hole transport layer 62 is formed uniformly over an entire display area of the active matrix substrate 70, so as to cover the first electrodes 61 and the edge cover 73. In the present embodiment, the hole injection layer-cum-hole transport layer 62 in which the hole injection layer and the hole transport layer are integrated is provided, but the present invention is not limited to this. The hole injection layer and the hole transport layer may be formed as layers independent from each other.

On the hole injection layer-cum-hole transport layer 62, the light emission layers 63 are formed so as to cover the openings 73A in the edge cover 73, corresponding to the pixels, respectively. The light emission layer 63 is a layer that has a function of recombining a hole injected from the first electrode 61 side and an electron injected from the second electrode 66 side so as to emit light. The light emission layer 63 contains a material having a high light emission efficiency such as a low-molecular fluorescent pigment, a metal complex, or the like.

The electron transport layer 64 is a layer that has a function of enhancing the efficiency of electron transport from the second electrode 66 to the light emission layer 63B. The electron injection layer 65 is a layer that has a function of enhancing the efficiency of electron injection from the second electrode 66 to the light emission layer 63. The second electrode 66 is a layer that has a function of injecting electrons into the organic EL layer 67. The electron transport layer 64, the electron injection layer 65, and the second electrode 66 are formed uniformly over an entire surface of the display area on the active matrix substrate 70.

In the present embodiment, the electron transport layer 64 and the electron injection layer 65 are provided as layers independent from each other, but the present invention is not limited to this. A single layer in which the two are integrated (i.e., an electron transport layer-cum-electron injection layer) may be provided. Incidentally, organic layers other than the light emission layer 63 may be omitted appropriately as required. Further, the organic EL layer 67 may further include a carrier blocking layer or another layer as required.

In the example illustrated in FIG. 29, the light-shielding film 111 is arranged at such a position that the light-shielding film 111 is superposed on the edge cover 73, when viewed in a direction vertical to the substrate 110B. In other words, the light-shielding film 111 is provided in an area other than the light emission area of each pixel. For example, the light-shielding film 111 can be provided in an area that is superposed on the lines such as the source lines or the gate lines. Alternatively, the light-shielding film 111 can be provided in an area superposed on the TFTs 300. This makes it possible to prevent light incident through the substrate 110B from being reflected on metals of the TFTs 300 and lines. Consequently, the display quality is improved.

In the example illustrated in FIG. 29, as is the case with Embodiment 1 or 2, the light-transmitting film 114 can be formed with a coating-type material.

Though not illustrated, the display device 10B is provided with a plurality of gate lines 16, and a plurality of source lines 15 arrayed so as to intersect with the gate lines 16, as is the case with Embodiment 1 or 2. The gate lines 16 are connected to the gate driver 14, and the source lines 15 are connected to the source driver 12. The source lines 15 are formed with, for example, the third conductive films 150.

The gate line 16 can be formed with, for example, the first conductive film 130 and the second conductive film 140. Forming the gate line 16 with the first conductive film 130 and the second conductive film 140 makes it possible to reduce the width of the gate line, thereby achieving a higher resolution. The first conductive film 130 and the second conductive film 140, composing the gate line 16, are not in direct contact with each other. The first conductive film 130 and the second conductive film 140 are electrically connected with each other via the third conductive film 150. In other words, as is the case with Embodiment 1, the first conductive film 130 and the third conductive film 150 are connected via the first contact hole CH1. Further, the third conductive film 150 and the second conductive film 140 are connected via the second contact hole CH2.

Incidentally, it is possible to form the capacitor line and the gate line 16 with conductive films different from the conductive films used in the example described above. The gate line 16 can be formed with, for example, the second conductive film 140, which is in the same layer as the gate electrode 141. The source line 15 can be formed with, for example, the first conductive film 130, in the display area.

Further, as is the case with Embodiment 1, the configuration may be as follows: in the display area, the source line 15 is formed with the first conductive film 130, and in the vicinity of the source driver 12. the source line 15 formed with the first conductive film 130 is electrically connected with the second conductive film 140 via the third conductive film 150.

At points of intersection of these source lines 15 and gate lines 16, pixels P are provided, respectively. In each pixel P, a TFT 300, and a first electrode 61 connected to the TFT 300, are included. The gate lines 16 are connected to the gates of the TFTs 300, the source lines 15 are connected to the sources of the TFTs 300, and the first electrodes 61 are connected to the drains of the TFTs 300. In this way. in the display device 10A, a plurality of areas of the pixels P are formed in the areas defined in matrix by the source lines 15 and the gate lines 16, respectively. In the display device 10A, an area where the pixels P are formed is the display area.

### Effects of Embodiment 3

In the display device 10B of the present embodiment, in the gate line 16, the first conductive film 130 and the second conductive film 140 are connected via the third conductive film 150. In other words, it is unnecessary to bring the first conductive film 130 and the second conductive film 140 into direct contact with each other in order to electrically connect the first conductive film 130 and the second conductive film 140, and it is unnecessary to form a contact hole in the light-transmitting film 114 before forming the second conductive film 140.

Since it is unnecessary to form a contact hole in the light-transmitting film 114 before forming the second conductive film 140, the third inorganic insulating film 115 and the semiconductor film 170 can be formed in a state in which no contact hole is formed in the light-transmitting film 114. In other words, in a state in which no contact hole is formed in the light-transmitting film 114, the semiconductor film 170 can be subjected to a high-temperature annealing treatment. When the semiconductor film 170 is annealed, therefore, the light-transmitting film 114 has no contact hole therein and hence it is flat. This makes it possible to prevent cracks from occurring to the light-transmitting film 114 due to heat during the high-temperature annealing treatment with respect to the semiconductor film 170. As a result, the yield and reliability of the active matrix substrate 70 can be improved.

### Modification Example of Embodiment 3

In the bottom emission type organic EL display, as in the present embodiment, it is useful to form the light-shielding layer on the display viewing side of conductive films such as gate electrodes, in order to prevent external light advancing from the display viewing side into the display device from being reflected on the conductive films. This light-shielding layer can be formed with the above-described light-shielding film 111 and light-transmitting film 114.

Further, the present invention can be applied to a top emission type organic EL display. In this case, the light-shielding film 111 in the above-described configuration is unnecessary.

### Other embodiments

In Embodiments 1 to 3 described above. the first substrate 11 includes bottom gate type TFTs 300, but the first substrate 11 may include top gate type TFTs 300.

In Embodiments 1 to 3 described above, the first substrate 11 includes the TFTs 300 that include the etching stopper film 117, but the etching stopper film 117 can be omitted.

The description of Embodiments 1 to 3 explains that the semiconductor film 302 of the TFT 300 is formed with a compound (In—Ga—Zn—O) containing indium (In), gallium (Ga), zinc (Zn), and, oxygen (O), but the present invention is not limited to this. The semiconductor layer of the TFT 300 may be formed with a compound (In—Tin—Zn—O) containing indium (In), tin (Tin), zinc (Zn), and oxygen (O), a compound (In—Al—Zn—O) containing indium (In), aluminum (Al), zinc (Zn), and oxygen (O), or the like.

The above-described embodiment is merely an example for implementing the present invention. The present invention, therefore, is not limited to the above-described embodiment, and the above-described embodiment can be appropriately varied and implemented without departing from the spirit and scope of the invention.

### INDUSTRIAL APPLICABILITY

The present invention is applicable to an active matrix substrate, a display device, and a method for producing an active matrix substrate.

### DESCRIPTION OF REFERENCE NUMERALS

10: display device
11: insulating substrate
110: active matrix substrate (first substrate)
111: light-shielding film
114: light-transmitting film
116: first insulating layer (gate insulating film)
118: second insulating layer (passivation film)
119: organic insulating film
130: first conductive film
140: second conductive film
150: third conductive film
160: fourth conductive film
170: semiconductor film
40: active matrix substrate
70: active matrix substrate
CH1: first contact hole
CH2: second contact hole

1. An active matrix substrate comprising:
an insulating substrate;
a first conductive film formed on the insulating substrate;
a light-transmitting film formed on the insulating substrate so that the light-transmitting film covers the first conductive film;
a second conductive film formed on the light-transmitting film;
a first insulating layer formed on the light-transmitting film so that the first insulating layer covers the second conductive film;
a semiconductor film formed on the first insulating layer; and
a third conductive film formed on the first insulating layer and the semiconductor film,
wherein the first conductive film and the second conductive film are electrically connected via the third conductive film.

2. The active matrix substrate according to claim 1,
wherein the first conductive film and the third conductive film are in contact with each other in a first contact hole that passes through the light-transmitting film and the first insulating layer, and the second conductive film and the third conductive film are in contact with each other in a second contact hole that passes through the first insulating layer, whereby the first conductive film and the second conductive film are electrically connected with each other.

3. The active matrix substrate according to claim 1, further comprising:
a second insulating layer formed on the first insulating layer so that the second insulating layer covers the third conductive film; and
a fourth conductive film formed on the second insulating layer.

4. The active matrix substrate according to claim 1, further comprising a light-shielding film formed on the insulating substrate,
wherein the first conductive film is provided on the insulating substrate and the light-shielding film.

5. The active matrix substrate according to claim 1,
wherein the light-transmitting film is an SOG film.

6. The active matrix substrate according to claim 1,
wherein the first conductive film has a film thickness of 500 to 1000 nm.

7. The active matrix substrate according to claim 1,
wherein the semiconductor film is formed with an oxide semiconductor.

8. A display device comprising the active matrix substrate according to claim 1.

9. The display device according to claim 8, further comprising:
a counter substrate opposed to the active matrix substrate; and
a liquid crystal layer provided between the active matrix substrate and the counter substrate.

10. The display device according to claim 8, further comprising an organic EL element formed in an upper layer with respect to the third conductive

11. A display device comprising the active matrix substrate according to claim 1, the display device further comprising:
a light-shielding film that is provided between the insulating substrate and the light-transmitting film, and that has a plurality of openings;
shutter mechanism parts formed in an upper layer with respect to the third conductive film; and
a backlight arranged so as to he opposed to the insulating substrate, with the shutter mechanism parts being interposed therebetween,
wherein the shutter mechanism parts include shutter bodies that control amount of light of the backlight that passes through the openings provided in the light-shielding film.

12. A method for producing an active matrix substrate, the method comprising:
a first step of forming a first conductive film on an insulating substrate;
a second step of forming a light-transmitting film on the insulating substrate so as to cover the first conductive film;
a third step of forming a second conductive film on the light-transmitting film;
a fourth step of forming a first insulating layer on the light-transmitting film so as to cover the second conductive film;
a fifth step of forming a semiconductor film on the first insulating layer, and thereafter, performing an annealing treatment;
a sixth step of forming a first contact hole that passes through the first insulating layer and the light-transmitting film and reaches the first conductive film, and a second contact hole that passes through the first insulating layer and reaches the second conductive film; and
a seventh step of forming a third conductive film on the first insulating layer and the semiconductor film,
wherein the fifth step is executed prior to the formation of the first contact hole in the light-transmitting film in the sixth step, and
in the seventh step, the first conductive film and the third conductive film are in contact with each other in the first contact hole, Which passes through the light-transmitting film and the first insulating layer, and the second conductive film and the third conductive film are in contact with each other in the second contact hole, which passes through the first insulating layer, whereby the first conductive film and the second conductive film are electrically connected.

13. The method for producing an active matrix substrate according to claim 12,
wherein, in the sixth step, the first insulating layer is patterned so that a part of the first contact hole as well as the second contact hole are formed, and thereafter the light-transmitting film is patterned so that the first contact hole is formed,

14. The method for producing an active matrix substrate according to claim 12,
wherein the semiconductor film is formed with an oxide semiconductor.
